(19) United States
(12) Patent Application Publication
(10) Pub. No.: US 2025/0246230 A1
(43) Pub. Date: Jul. 31, 2025

(54) INTEGRATED CIRCUIT STRUCTURE AND METHOD FOR FABRICATING THE SAME

(71) Applicant: TAIWAN SEMICONDUCTOR MANUFACTURING COMPANY, LTD., Hsinchu (TW)

(72) Inventor: Jhon Jhy LIAW, Hsinchu County (TW)

(73) Assignee: TAIWAN SEMICONDUCTOR MANUFACTURING COMPANY, LTD., Hsinchu (TW)

(21) Appl. No.: 18/428,967

(22) Filed: Jan. 31, 2024

(51) Int. Cl. G11C 11/412; G11C 11/419; H01L 23/528; H10B 10/00

(52) U.S. Cl. CPC G11C 11/412; G11C 11/419; H10B 10/12; H01L 23/5286

(57) ABSTRACT

A method includes forming a static random access memory (SRAM) array in a device layer, wherein the SRAM array comprises a first SRAM cell and a second SRAM cell adjacent to the first SRAM cell, and from a top view, the first and second SRAM cells are arranged in a first direction; forming a first word line over a front-side of the device layer and extending across the first and second SRAM cells in the first direction, wherein the first word line is electrically coupled to the first SRAM cell; forming a bit line and a bit line bar over a back-side of the device layer, wherein the first and second SRAM cells share the bit line and the bit line bar.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a circuit diagram of a static random access memory (SRAM) cell according to some embodiments of the present disclosure.

FIG. 1B illustrates a block diagram of an array of SRAM cells according to some embodiments of the present disclosure.

FIGS. 2-10B illustrate layouts and cross-sectional views of an integrated circuit structure at intermediate stages of fabrication process according to some embodiments of the present disclosure.

FIG. 11 is a cross-sectional view of an integrated circuit chip according to some embodiments of the present disclosure.

FIGS. 12A and 12B illustrate layouts of an integrated circuit structure according to some embodiments of the present disclosure.

FIGS. 13A and 13B illustrate layouts of an integrated circuit structure according to some embodiments of the present disclosure.

FIG. 14A illustrates a block diagram of an integrated circuit structure according to some embodiments of the present disclosure.

FIG. 14B is a cross-sectional view of a tap structure of the integrated circuit chip of FIG. 14A.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The present disclosure is related to integrated circuit (IC) structures and methods of forming the same. More particularly, some embodiments of the present disclosure are related to gate-all-around (GAA) devices including improved isolation structures to reduce current leakage from channels to the substrate. A GAA device includes a device that has its gate structure, or portions thereof, formed on four-sides of a channel region (e.g., surrounding a portion of a channel region). The channel region of a GAA device may include nanosheet channels, bar-shaped channels, and/or other suitable channel configurations. In some embodiments, the channel region of a GAA device may have multiple horizontal nanosheets or horizontal bars vertically spaced, making the GAA device a stacked horizontal GAA (S-HGAA) device. The GAA devices presented herein include a p-type metal-oxide-semiconductor GAA device and an n-type metal-oxide-semiconductor GAA device stack together. Further, the GAA devices may have one or more channel regions (e.g., nanosheets) associated with a single, contiguous gate structure, or multiple gate structures. One of ordinary skill may recognize other examples of semiconductor devices that may benefit from aspects of the present disclosure. In some embodiments, the nanosheets can be interchangeably referred to as nanowires, nanoslabs, nanorings, or nanostructures having nano-scale size (e.g., a few nanometers), depending on their geometry. In addition, the embodiments of the disclosure may also be applied, however, to a variety of metal oxide semiconductor transistors (e.g., complementary-field effect transistor (CFET) and fin field effect transistor (FinFET)).

Some embodiments discussed herein are discussed in the context of nano-FETs formed using a gate-last process. In other embodiments, a gate-first process may be used. Also, some embodiments contemplate aspects used in planar devices, such as planar FETs, or in fin field-effect transistors (FinFETs). For example, FinFETs may include fins on a substrate, with the fins acting as channel regions for the FinFETs. Similarly, planar FETs may include a substrate, with portions of the substrate acting as channel regions for the planar FETs.

The SRAM stability is increasingly challenged by device scaling. For SRAM bit-lines, positioning them in the lowest metallization layer is preferred to reduce bit-line capacitance. However, within the tall SRAM cell structure, where the X-pitch (word-line length) is shorter than the Y-pitch (bit-line length), bit-line routing becomes congested. The narrower X-pitch dimension forces bit-lines into higher metal layers, leading to a more complex metal layout and increased bit-line capacitance. Therefore, the present disclosure in various embodiments provides a method to position the low power rail Vss1, the bit lines BL, and the bit line bars BLB at the back-side of the wafer, which in turn reduces routing load and facilitates reduction in cell size. Having fewer metal tracks within the same layer can enhance the metal conductor's RC (resistance-capacitance) performance. This results in both lower resistance, due to increased metal width, and reduced capacitance, achieved by creating larger spaces between metal tracks. Additionally, the word-line routing and pass gate device strap settings can organize horizontal cells into groups to two rows. By merging two cells with a single bit-line pair (e.g., bit line and bit line bar), an additional space for the bit line and the bit line bar can be created, allowing for either wider bit line/bit line bar width in larger arrays (with more columns and rows), increased metal spacing to reduce capacitance.

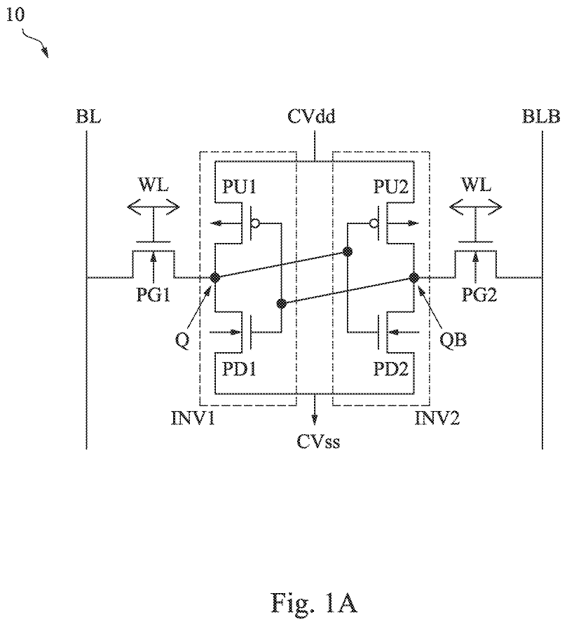

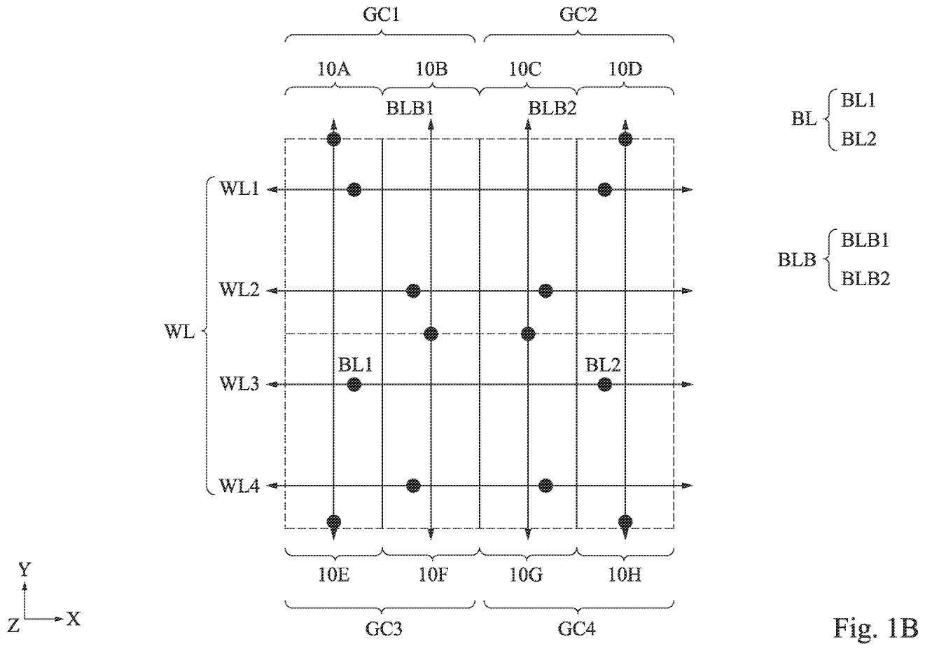

Reference is made to FIGS. 1A and 1B. FIG. 1A is a circuit diagram of a static random access memory (SRAM) cell 10 according to some embodiments of the present disclosure. FIG. 1B illustrates a block diagram of an array of SRAM cells according to some embodiments of the present disclosure. As shown in FIG. 1A, SRAM cell 10 includes pull-up transistors PU1 and PU2, which are of first conductivity type, and pull-down transistors PD1 and PD2 and pass-gate transistors PG1 and PG2, which are second conductivity type opposite to the first conductivity type. By way of example and not limitation, the pull-up transistors PU1 and PU2 can be p-type Metal-Oxide-Semiconductor (PMOS) transistors, and pull-down transistors PD1 and PD2 and pass-gate transistors PG1 and PG2 can be n-type Metal-Oxide-Semiconductor (NMOS) transistors.

The gates of pass-gate transistors PG1 and PG2 are controlled by a word line WL that determines whether SRAM cell 10 is selected or not. A latch formed of pull-up transistors PU1 and PU2 and pull-down transistors PD1 and PD2 stores a bit, wherein the complementary values of the bit are stored in storage data nodes Q and QB. The stored bit can be written into, or read from, SRAM cell 10 through complementary bit lines including a bit line BL and a bit line bar BLB. SRAM cell 10 is powered through a positive power supply node CVdd that has a positive power supply voltage. SRAM cell 10 is also connected to a power supply voltage node CVss, which may be an electrical ground. Transistors PU1 and PD1 form a first inverter INV1. Transistors PU2 and PD2 form a second inverter INV2. The first and second inverters INV1 and INV2 are cross-latched. For example, the input of the first inverter INV1 (e.g., gates of the transistors PU1 and PD1) is connected to the output of the second inverter INV2 (e.g., drains of the transistors PU2 and PD2), and the output of the first inverter INV1 (e.g., drains of the transistors PU1 and PD1) is connected to the input of the second inverter INV2 (e.g., gates of the transistors PU2 and PD2). The input of the first inverter INV1 is also connected to the transistor PG2. The output of the first inverter is also connected to the transistor PG1.

The sources of pull-up transistors PU1 and PU2 are connected to positive power supply node CVdd. The sources of pull-down transistors PD1 and PD2 are connected to the power supply voltage node CVss. The gates of transistors PU1 and PD1 are connected to the drains of transistors PU2 and PD2, which form a connection node that is referred to as storage data node QB. The gates of transistors PU2 and PD2 are connected to the drains of transistors PU1 and PD1, which form a connection node is referred to as storage data node Q. A source/drain region of pass-gate transistor PG1 is connected to the bit line BL. A source/drain region of pass-gate transistor PG2 is connected to the bit line bar BLB.

As shown in FIG. 1B, two adjacent SRAM cells in a same row may share a same bit line, a same bit line bar, and coupled to different word lines, respectively. For example, there are four groups GC1-GC4, and each of the groups GC1-GC4 may include two SRAM cells in the same row. For the group GC1, two adjacent SRAM cells 10A and 10B may share a bit line BL1 and a bit line bar BLB1, and be coupled to word lines WL1 and WL2, respectively. For the group GC2, two adjacent SRAM cells 10C and 10D share a bit line BL2 and a bit line bar BLB2, and coupled to the word lines WL1 and WL2, respectively. For the group GC3, two adjacent SRAM cells 10E and 10F may share the bit line BL1 and the bit line bar BLB1, and be coupled to word lines WL3 and WL4, respectively. For the group GC4, two adjacent SRAM cells 10G and 10H share the bit line BL2 and the bit line bar BLB2, and coupled to the word lines WL3 and WL4, respectively. For clear illustration, plural SRAM cells 10 are labelled as SRAM cells 10A-10H, plural bit lines BL are labelled as bit lines BL1 and BL2, plural bit line bars BLB are labelled as bit lines BLB1 and BLB2, and plural word lines WL are labelled as word lines WL1-WL4.

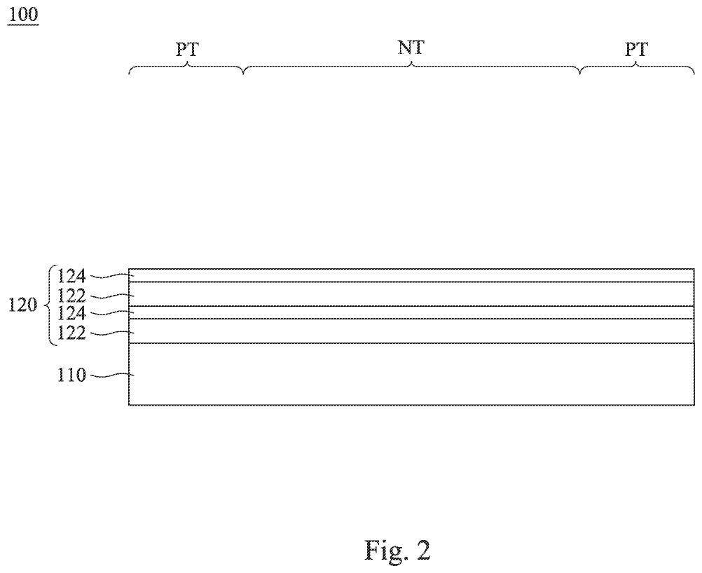

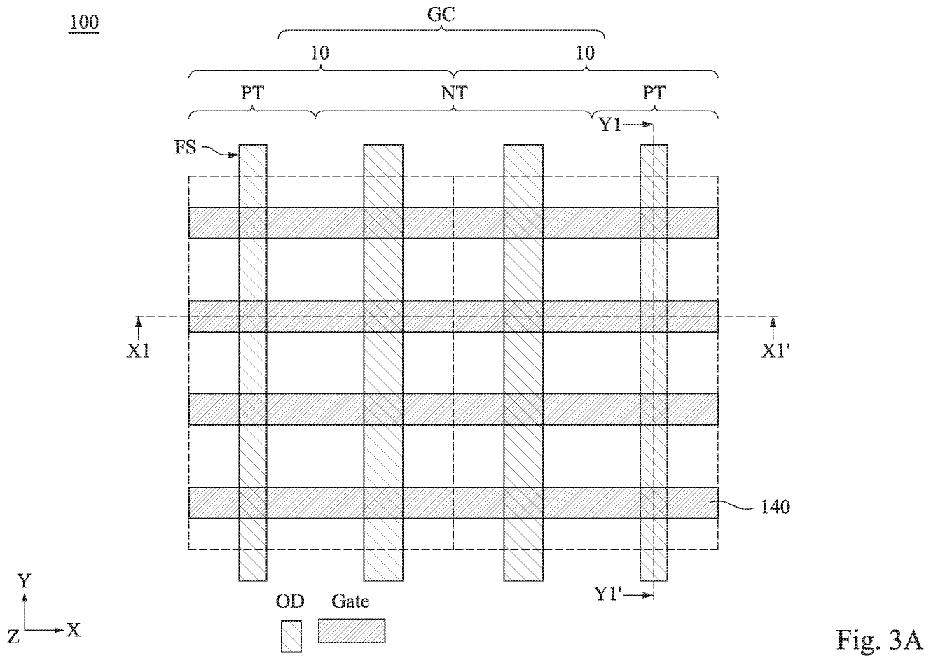

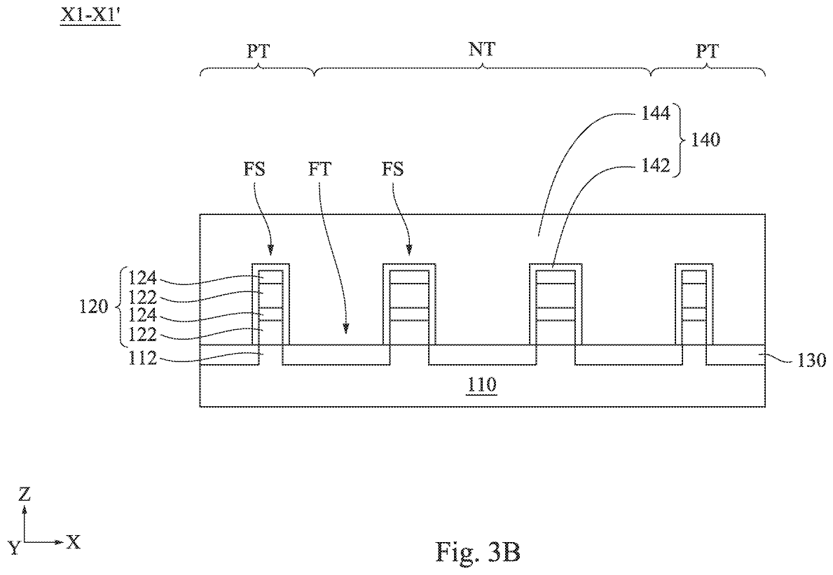

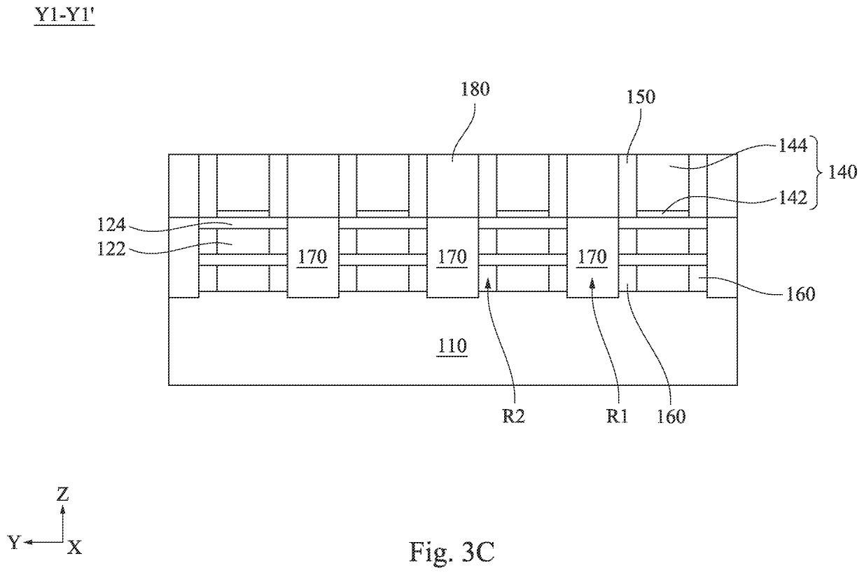

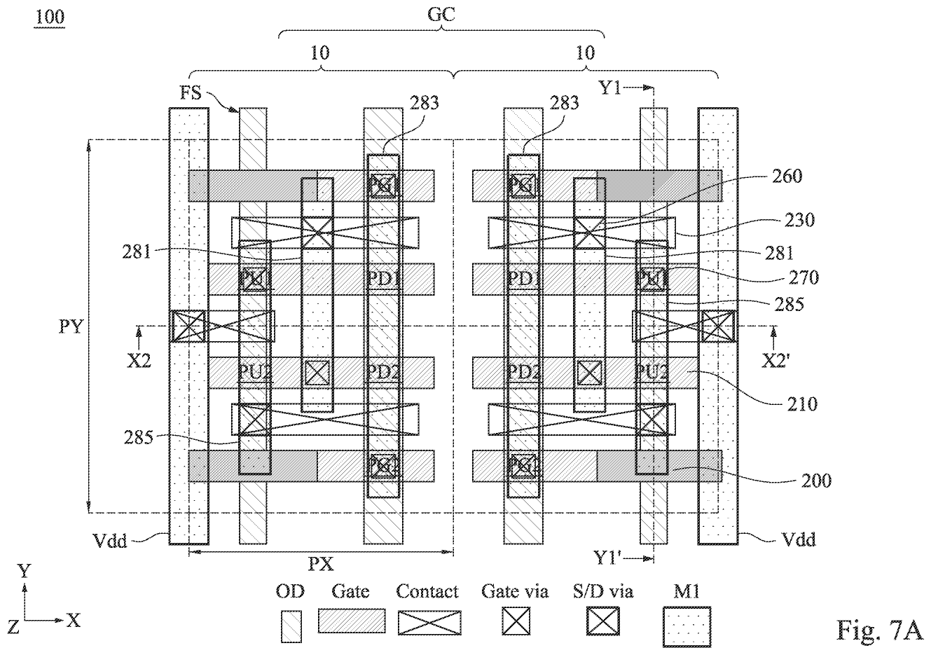

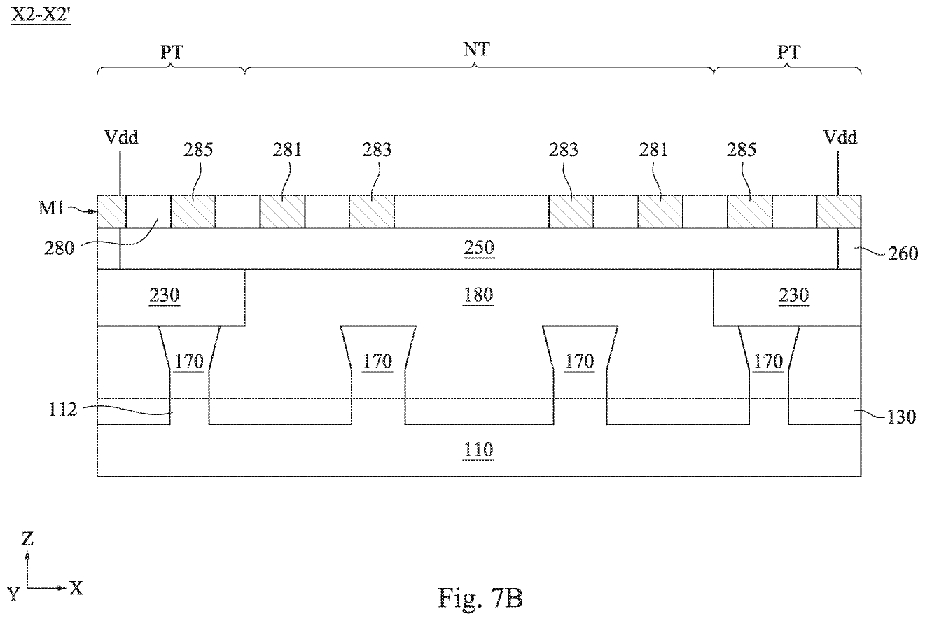

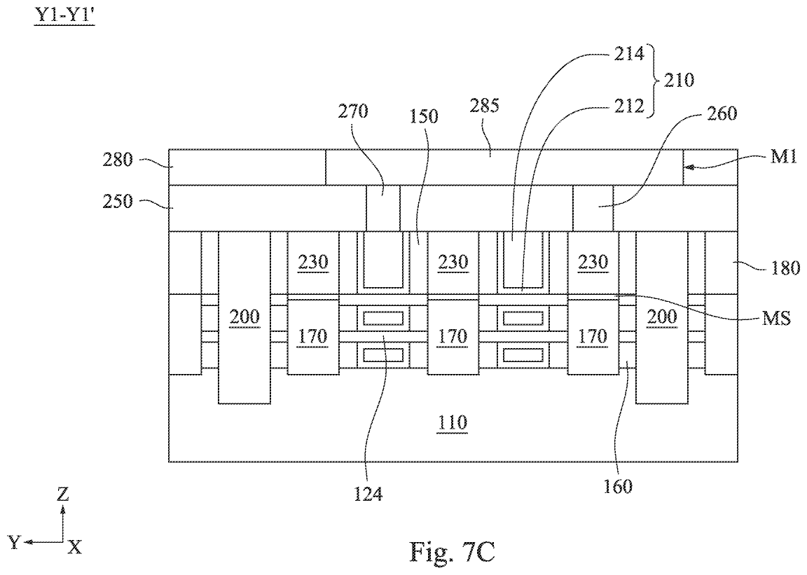

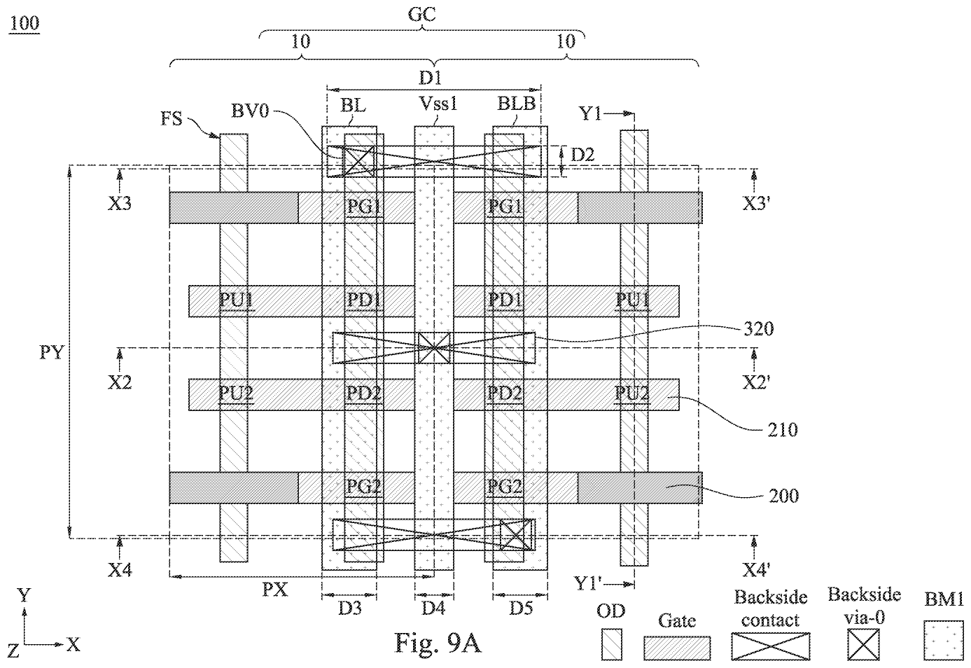

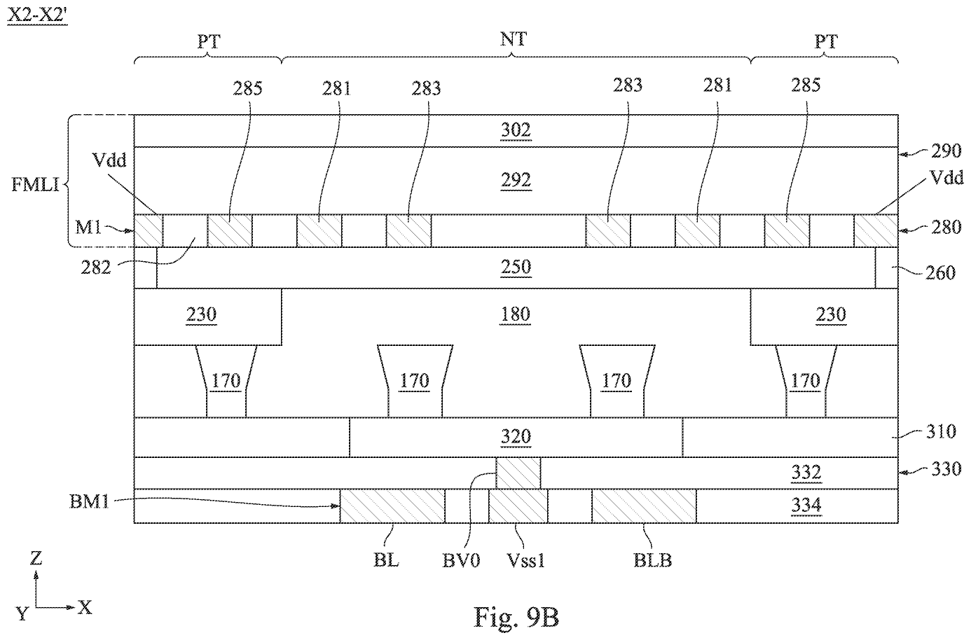

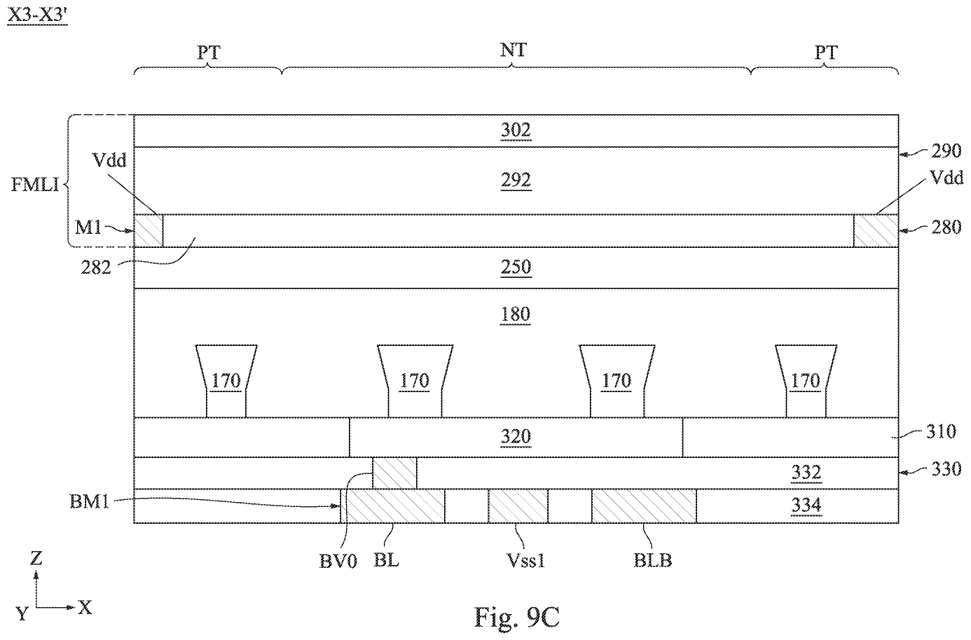

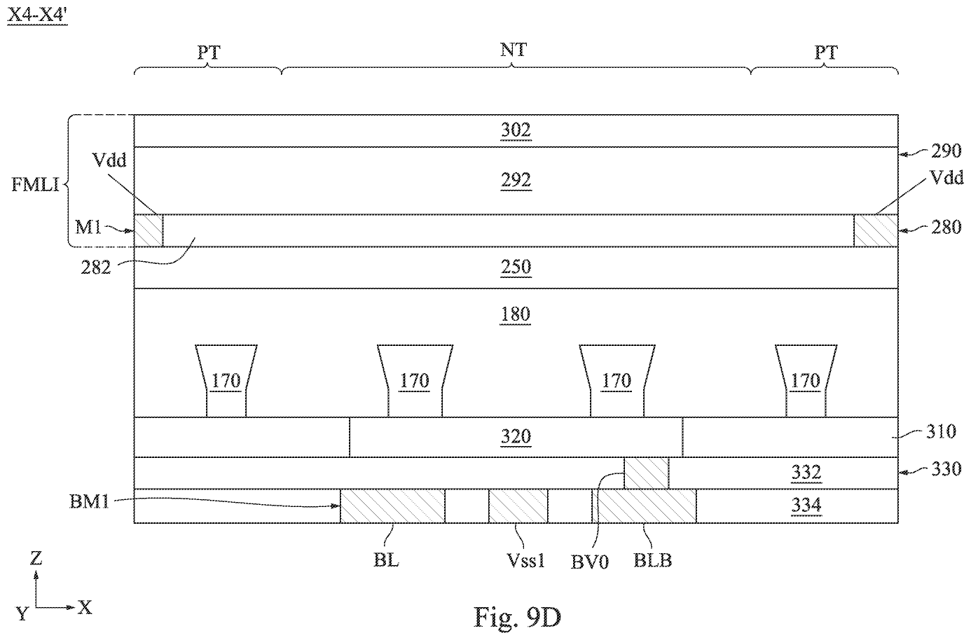

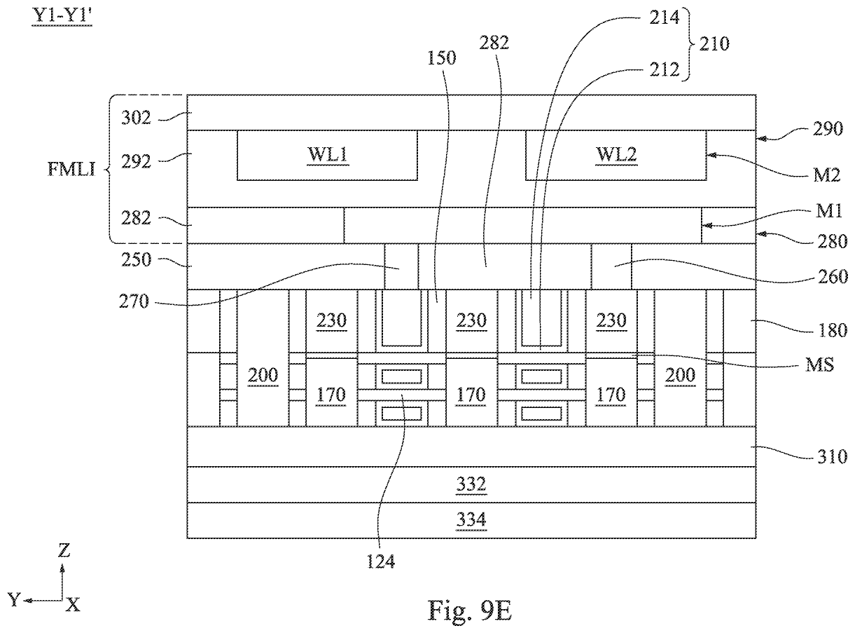

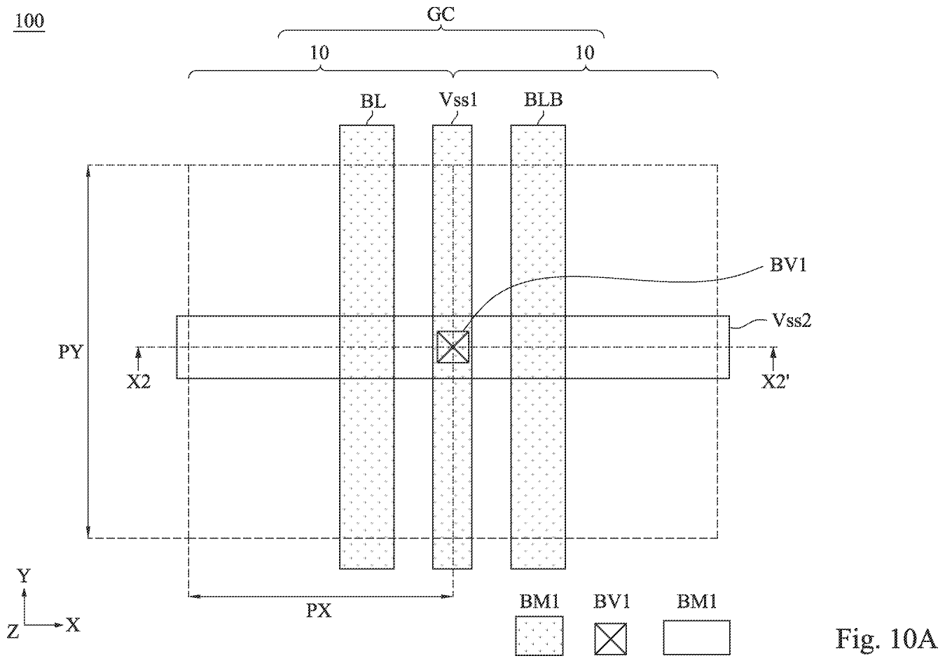

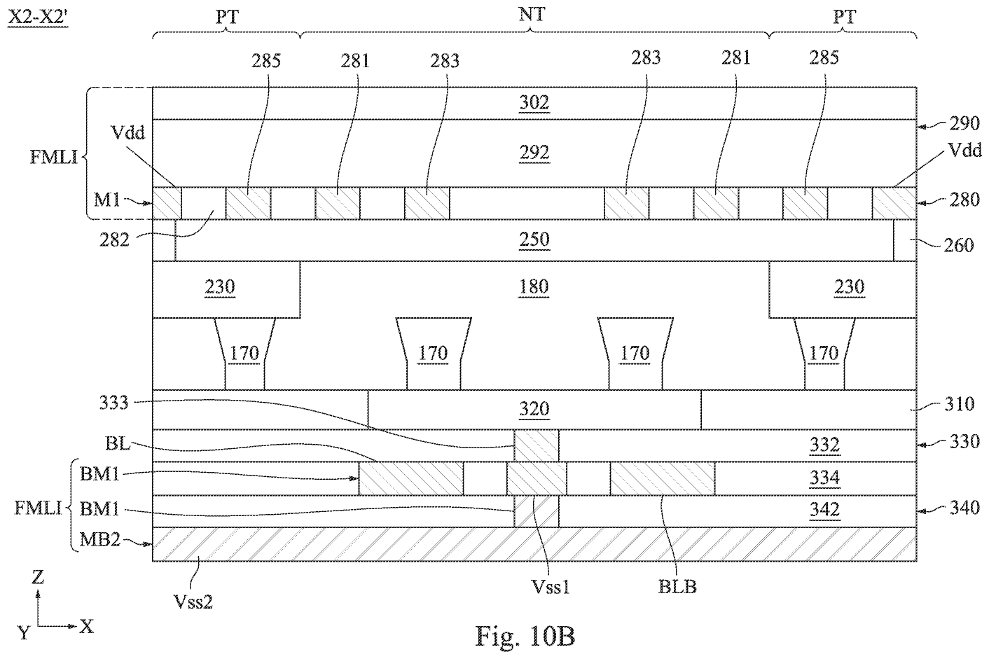

Reference is made to FIGS. 2-10B. FIGS. 2-10B illustrate layouts and cross-sectional views of an integrated circuit structure 100 at intermediate stages of fabrication process according to some embodiments of the present disclosure. FIGS. 3A, 4A, 5A, 6A, 7A, 8A, 9A, and 10A are layouts of the integrated circuit structure 100 at the intermediate stages of fabrication process according to some embodiments of the present disclosure, in which FIGS. 3A, 4A, 5A, 6A, 7A, and 8A show front-side layouts, and FIGS. 9A and 10A show back-side layouts, while all the front-side layouts and back-side layouts are illustrated as being viewed from top/front side. In the layouts of FIGS. 3A, 4A, 5A, 6A, 7A, 8A, 9A, and 10A, boundaries of standard cells 10 are shown, in which the standard cells 10 corresponds to a static random access memory (SRAM). FIGS. 3B, 4B, and 5B illustrate cross-sectional views taken along line X1-X1′ in FIGS. 3A, 4A, and 5A respectively. FIGS. 7B, 9B, and 10B illustrate cross-sectional views taken along line X2-X2′ in FIGS. 7A, 9A, and 10A, respectively. FIG. 9C illustrates a cross-sectional view taken along line X3-X3′ in FIG. 9A. FIG. 9D illustrates a cross-sectional view taken along line X4-X4′ in FIG. 9A. FIGS. 3C, 4C, 6B, 7C, 8B, and 9D illustrate cross-sectional views taken along line Y1-Y1 in FIGS. 3A, 4A, 6A, 7A, 8A, and 9A, respectively.

As with the other method embodiments and exemplary devices discussed herein, it is understood that parts of the integrated circuit structure 100 may be fabricated by a CMOS technology process flow, and thus some processes are only briefly described herein. Further, the exemplary integrated circuit structure 100 may include various other devices and features, such as other types of devices such as additional transistors, bipolar junction transistors, resistors, capacitors, inductors, diodes, fuses, and/or other logic circuits, etc., but is simplified for a better understanding of the concepts of the present disclosure. In some embodiments, the exemplary integrated circuit structure 100 includes a plurality of semiconductor devices (e.g., transistors), including PFETs, NFETs, etc., which may be interconnected. It is understood that additional operations can be provided before, during, and after the processes shown by FIGS. 2-10B, and some of the operations described below can be replaced or eliminated, for additional embodiments of the method. The order of the operations/processes may be interchangeable.

Reference is made to FIG. 2. FIG. 2 shows an initial structure. The initial structure includes a substrate 110. In some embodiments, the substrate 110 may include silicon (Si). Alternatively, the substrate 110 may include germanium (Ge), silicon germanium (SiGe), a III-V material (e.g., GaAs, GaP, GaAsP, AlInAs, AlGaAs, GaInAs, InAs, GaInP, InP, InSb, and/or GaInAsP; or a combination thereof) or other appropriate semiconductor materials. In some embodiments, the substrate 110 may include a semiconductor-on-insulator (SOI) structure. For example, the substrate 110 may include a bulk semiconductor substrate, a buried dielectric layer over the bulk substrate, and a semiconductor layer over the buried dielectric layer. The substrate 110 may include a first conductivity type device region PT where first conductivity type devices are to be formed thereon, and a second conductivity type device region NT where second conductivity type devices are to be formed thereon. By way of example and not limitation, the p-type devices (e.g., PMOSFET) can be formed on the first conductivity type device region PT, and the n-type devices (e.g., NMOSFET) can be formed on the first conductivity type device region NT.

An epitaxial stack 120 is formed over the substrate 110. The epitaxial stack 120 includes epitaxial layers 122 of a first composition interposed by epitaxial layers 124 of a second composition. The first and second compositions can be different. In some embodiments, the epitaxial layers 122 are SiGe and the epitaxial layers 124 are silicon (Si). However, other embodiments are possible including those that provide for a first composition and a second composition having different oxidation rates and/or etch selectivity. In some embodiments, the epitaxial layers 122 include SiGe and where the epitaxial layers 124 include Si, the Si oxidation rate of the epitaxial layers 124 is less than the SiGe oxidation rate of the epitaxial layers 122.

The epitaxial layers 124 or portions thereof may form nanosheet channel(s) of the multi-gate transistor. The term nanosheet is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including for example a cylindrical in shape or substantially rectangular cross-section. The use of the epitaxial layers 124 to define a channel or channels of a device is further discussed below. It is noted that two layers of the epitaxial layers 122 and two layers of the epitaxial layers 124 are alternately arranged as illustrated in FIG. 2. It can be appreciated that any number of epitaxial layers can be formed in the epitaxial stack 120; the number of layers depending on the desired number of channels regions for the transistor. In some embodiments, the number of epitaxial layers 124 is between 2 and 10. In some embodiments, the epitaxial layer 124 can be interchangeably referred to as a channel region, a channel pattern, or a semiconductive layer.

In some embodiments, the epitaxial layers 122 may be substantially uniform in thickness, and the epitaxial layers 124 of the stack are substantially uniform in thickness. As described in more detail below, the epitaxial layers 124 may serve as channel region(s) for a subsequently-formed multi-gate device and the thickness is chosen based on device performance considerations. The epitaxial layers 122 in channel regions(s) may eventually be removed and serve to define a vertical distance between adjacent channel region(s) for a subsequently-formed multi-gate device and the thickness is chosen based on device performance considerations. Accordingly, the epitaxial layers 122 may also be referred to as sacrificial layers, and epitaxial layers 124 may also be referred to as channel layers. The structure of said devices are formed by either FinFET transistors, or GAA transistors, or CFET (vertical stacked N/P MOSFETs) or SOI planar transistors, or SOI fin-structure (3D) transistors, or SOI GAA transistors, or combination. The channel region of the GAA device can be nana-wire, or nano-sheet, or fork-sheet and have vertically stacked multiple channels (sheets or wires), or combination.

By way of example, epitaxial growth of the layers of the stack 120 may be performed by a molecular beam epitaxy (MBE) process, a metalorganic chemical vapor deposition (MOCVD) process, and/or other suitable epitaxial growth processes. In some embodiments, the epitaxially grown layers such as, the epitaxial layers 124 include the same material as the substrate 110. In some embodiments, the epitaxially grown layers 122 and 124 include a different material than the substrate 110. As stated above, in at least some examples, the epitaxial layers 122 include an epitaxially grown silicon germanium (SiGe) layer and the epitaxial layers 124 include an epitaxially grown silicon (Si) layer. Alternatively, in some embodiments, either of the epitaxial layers 122 and 124 may include other materials such as germanium, a compound semiconductor such as silicon carbide, gallium arsenide, gallium phosphide, indium phosphide, indium arsenide, and/or indium antimonide, an alloy semiconductor such as SiGe, GaAsP, AlInAs, AlGaAs, InGaAs, GaInP, and/or GaInAsP, or combinations thereof. As discussed, the materials epitaxial layers 122 and 124 may be chosen based on providing differing oxidation and/or etching selectivity properties. In some embodiments, the epitaxial layers 122 and 124 are substantially dopant-free (i.e., having an extrinsic dopant concentration from about 0 cm 3 to about 1×10¹⁸ cm 3), where for example, no intentional doping is performed during the epitaxial growth process.

Reference is made to FIGS. 3A-3C. The epitaxial stack 120 and the substrate 110 are patterned, thereby forming plural fins FS (see FIGS. 3A and 3B). The fins FS may extend along direction X. The patterning may include suitable lithography process and etching processes. The lithography process (e.g., photolithography or e-beam lithography) may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etching process may include dry etching (e.g., reactive ion etching), wet etching, and/or other etching methods. In some embodiments, masks are formed over the epitaxial stack 120 by the photolithography process. The masks are used to protect regions of the substrate 110 and the epitaxial stack 120, while etching processes form trenches FT in unprotected regions through the epitaxial stack 120 and into the substrate 110, thereby leaving the plurality of extending fins FS.

In some alternative embodiments, the fins FS may be fabricated using suitable processes including double-patterning or multi-patterning processes. The double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the fins FS by etching initial epitaxial stack 120. The etching process can include dry etching, wet etching, reactive ion etching (RIE), and/or other suitable processes. Numerous other embodiments of methods to form the fins on the substrate may also be used including, for example, defining the fin region (e.g., by mask or isolation regions) and epitaxially growing the epitaxial stack 120 in the form of the fins FS. In various embodiments, each of the fins FS includes a base portion 112 patterned from the semiconductor substrate 110 and portions of each of the epitaxial layers 122 and 124 of the epitaxial stack 120.

Subsequently, isolation structures 130 (see FIG. 3B) are formed in the trenches FT (see FIG. 3B) between the fins FS. In some embodiments, the isolation structure 130 can be formed to laterally surround the fin FS. The isolation structures 130 may be referred to as shallow trench isolation (STI) structures. By way of example and not limitation, a dielectric layer is first deposited over the substrate 110, filling the trenches FT with the dielectric material. In some embodiments, the dielectric layer may include silicon oxide, silicon nitride, silicon oxynitride, fluorine-doped silicate glass (FSG), a low-k dielectric, combinations thereof, and/or other suitable materials. In various examples, the dielectric layer may be deposited by a CVD process, a subatmospheric CVD (SACVD) process, a flowable CVD process, an ALD process, a physical vapor deposition (PVD) process, and/or other suitable processes. In some embodiments, the dielectric layer may include a multi-layer structure, for example, having one or more liner layers. In some embodiments, after deposition of the dielectric layer, the deposited dielectric material is thinned and planarized, for example by a chemical mechanical polishing (CMP) process. In the layouts, regions between the isolation structures 130 are indicated as oxide-defined (OD) regions, which correspond to the fins FS. The isolation (or STI) structures 130 are recessed in an etch back process, such that the oxide-defined (OD) regions (e.g., fins FS) has exposed sidewall extending above the isolation structure 130. In some embodiments, the recessing process may include a dry etching process, a wet etching process, and/or a combination thereof. In some embodiments, a recessing depth is controlled (e.g., by controlling an etching time) so as to result in a target height of the exposed upper portion of the fins FS. The target height may expose sidewalls of the OD regions (e.g., fins FS). In the illustrated embodiments, the target height exposes each of the epitaxial layers 122 and 124 of the epitaxial stack 120 in the fins FS.

Subsequently, a dummy gate dielectric layer 142 (see FIGS. 3B and 3C) is then conformally deposited in the trenches FT and over the isolation structures 130. In some embodiments, the dummy gate dielectric layer 142 may include SiO₂, silicon nitride, a high-k dielectric material and/or other suitable material. In various examples, the dummy gate dielectric layer 142 may be deposited by a CVD process, a subatmospheric CVD (SACVD) process, a flowable CVD process, an ALD process, a PVD process, or other suitable process. By way of example, the dummy gate dielectric layer 142 may be used to prevent damages to the fins FS by subsequent processes (e.g., subsequent formation of the dummy gate structures). Subsequently, the dummy gate electrode layer 144 can be deposited over the dummy gate dielectric layer 142. In some embodiments, the dummy gate electrode layer 144 may include polycrystalline silicon (polysilicon). In some embodiments, the dummy gate electrode layer 144 may be deposited by a CVD process, a subatmospheric CVD (SACVD) process, an ALD process, a PVD process, or other suitable process.

Subsequently, the dummy gate electrode layer 144 can be patterned to form dummy gate structures 140. The dummy gate structures 140 can be formed to extend along the direction Y intersecting the direction X that the fins FS extend along. For example, the direction Y is orthogonal to the direction X. The dummy gate structures 140 each include the dummy gate dielectric layer 142 and a dummy gate electrode layer 144. In some embodiments, the dummy gate structures 140 are formed by various process steps such as layer deposition, patterning, etching, as well as other suitable processing steps. Exemplary layer deposition processes include CVD (including both low-pressure CVD and plasma-enhanced CVD), PVD, ALD, thermal oxidation, e-beam evaporation, or other suitable deposition techniques, or combinations thereof. In forming the gate structures for example, the patterning process includes a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etching process may include dry etching (e.g., RIE etching), wet etching, and/or other etching methods. In some embodiments, after patterning the dummy gate electrode layer 144, exposed portions of the dummy gate dielectric layer 142 not covered under the patterned dummy gate electrode layer 144 are removed from source/drain regions of the fins FS. The etch process may include a wet etch, a dry etch, and/or a combination thereof. In some embodiments, the dummy gate structure 140 can be interchangeably referred to a dummy gate, a dummy gate pattern, a dummy gate strip, an isolation structure, or a dielectric gate.

Subsequently, gate spacers 150 (see FIG. 3C) are formed on sidewalls of the dummy gate structures 140. The gate spacers 150 may include a dielectric material such as SiO₂, Si₃N₄, carbon doped oxide, nitrogen doped oxide, porous oxide, or the combination thereof. The gate spacers 150 may include multiple dielectric materials. In some embodiments, the gate spacers 150 may further include air gaps. In some embodiments of formation of the gate spacers 150, a spacer material layer is first deposited over the substrate 110. The spacer material layer may be a conformal layer that is subsequently etched to form gate sidewall spacers on sidewalls of the dummy gate structures 140. In the illustrated embodiments, a spacer material layer is disposed conformally on top and sidewalls of the dummy gate structures 140. By way of example, the spacer material layer may be formed by depositing a dielectric material over the gate structures 140 using processes such as, CVD process, a subatmospheric CVD (SACVD) process, a flowable CVD process, an ALD process, a PVD process, or other suitable process. An anisotropic etching process is then performed on the deposited spacer material layer to expose portions of the fins FS not covered by the dummy gate structures 140 (e.g., in source/drain regions of the fins FS). Portions of the spacer material layer directly above the dummy gate structures 140 may be completely removed by this anisotropic etching process, and other portions of the spacer material layer on sidewalls of the dummy gate structures 140 may remain, forming gate sidewall spacers, which are denoted as the gate spacers 150, for the sake of simplicity. The gate spacers 150 serve to isolate metal gates from source/drain contacts formed in subsequent processing.

Subsequently, exposed portions of the semiconductor fins FS that extend laterally beyond the gate spacers 150 (e.g., in source/drain regions S/D of the fins FS) are etched by using, for example, an anisotropic etching process that uses the dummy gate structures 140 and the gate spacers 150 as an etch mask, resulting in recesses R1 into the semiconductor fins FS and between corresponding dummy gate structures 140. In some embodiments, the recesses R1 extends through the channel regions to the substrate 110 for exposing the epitaxial layers 122 and epitaxial layers 124.

Subsequently, the epitaxial layers 122 may be laterally recessed by using suitable etch techniques, resulting in lateral recesses R2 each vertically between corresponding epitaxial layers 124. This step may be performed by using a selective etching process. By way of example and not limitation, the epitaxial layers 122 are SiGe and the epitaxial layers 124 are silicon allowing for the selective etching of the epitaxial layers 122. In some embodiments, the selective wet etching includes an APM etch (e.g., ammonia hydroxide-hydrogen peroxide-water mixture) that etches SiGe at a faster etch rate than it etches Si. In some embodiments, the selective etching includes SiGe oxidation followed by a SiGeOₓ removal. For example, the oxidation may be provided by O₃ clean and then SiGeOₓ removed by an etchant such as NH₄OH that selectively etches SiGeOₓ at a faster etch rate than it etches Si. Moreover, because oxidation rate of Si is much lower than oxidation rate of SiGe, the epitaxial layers 124 remain substantially intact during laterally recessing the epitaxial layers 122. As a result, the epitaxial layers 124 laterally extend past opposite end surfaces of the epitaxial layers 122.

Subsequently, inner spacers 160 are formed in the recesses R2 left by the lateral etching of the epitaxial layers 122. For example, the inner spacers 160 can include a suitable dielectric material, such as SiO₂, Si₃N₄, SiON, SiOC, SiOCN, the like, or the combination thereof. Formation of the inner spacers 160 may include depositing an inner spacer material layer is formed to fill the recesses R2. The inner spacer material layer may be deposited by a suitable deposition method, such as ALD. After the deposition of the inner spacer material layer, an anisotropic etching process may be performed to trim the deposited inner spacer material, such that only portions of the deposited inner spacer material that fill the recesses left by the lateral etching of the epitaxial layers 122 are left. After the trimming process, the remaining portions of the deposited inner spacer material are denoted as inner spacers 160. The inner spacers 160 serve to isolate metal gates from source/drain epitaxial structures formed in subsequent processing.

Subsequently, source/drain epitaxial structures 170 are formed in the recesses R1 in the fins FS. The source/drain epitaxial structures 170 may be formed by performing an epitaxial growth process that provides an epitaxial material on the fins FS. Suitable epitaxial processes include CVD deposition techniques (e.g., vapor-phase epitaxy (VPE) and/or ultra-high vacuum CVD (UHV-CVD)), molecular beam epitaxy, and/or other suitable processes. The epitaxial growth process may use gaseous and/or liquid precursors, which interact with the composition of semiconductor materials of the fins FS and the epitaxial layers 124. The source/drain epitaxial structures 170 may be in-situ doped during the epitaxial process by introducing doping species including: p-type dopants, such as boron; n-type dopants, such as phosphorus or arsenic; and/or other suitable dopants including combinations thereof. If the source/drain epitaxial structures 170 are not in-situ doped, an implantation process (i.e., a junction implant process) is performed to dope the source/drain epitaxial structures 170. In some exemplary embodiments, the source/drain epitaxial structures 170 in an NFET device include SiP, SiC, SiPC, SiAs, Si, or combination thereof. The n-type doping concentration of the source/drain epitaxial structures 170 (e.g., phosphorus, arsenic, or both) in the NFET device may be in a range from about 2E19/cm³ to about 3E21/cm³. In some exemplary embodiments, the source/drain epitaxial structures 170 in a PFET device include SiGe doped with boron, or SiGeC doped with boron, Ge doped with boron, Si doped with boron, or combination. The p-type doping concentration of the source/drain epitaxial structures 170 (e.g., boron) in the PFET device may be in a range from about 1E19/cm³ to about 6E20/cm³. In some embodiments, the source/drain epitaxial structure 170 can be interchangeably referred to as a source/drain region or an epitaxial pattern.

Subsequently, a dielectric material 180 is formed over the substrate 110 and filling the space between the dummy gate structures 140. In some embodiments, the dielectric material 180 includes a contact etch stop layer (CESL) and an interlayer dielectric (ILD) layer formed in sequence. In some examples, the CESL includes a silicon nitride layer, silicon oxide layer, a silicon oxynitride layer, and/or other suitable materials having a different etch selectivity than the ILD layer. The CESL may be formed by plasma-enhanced chemical vapor deposition (PECVD) process and/or other suitable deposition or oxidation processes. The ILD layer is then deposited over the CESL. In some embodiments, the ILD layer includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the CESL. The ILD layer may be deposited by a PECVD process or other suitable deposition technique. After depositing the dielectric material 180, a planarization process may be performed to remove excessive materials of the dielectric material 180. For example, a planarization process includes a chemical mechanical planarization (CMP) process which removes portions of the dielectric material 180 overlying the dummy gate structures 140 and planarizes a top surface of the integrated circuit structure.

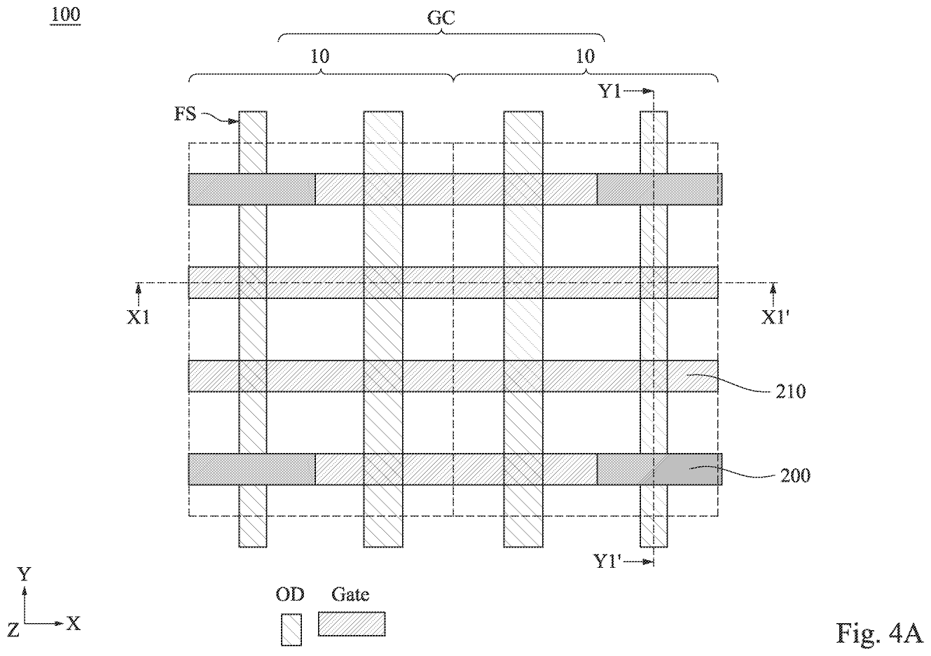

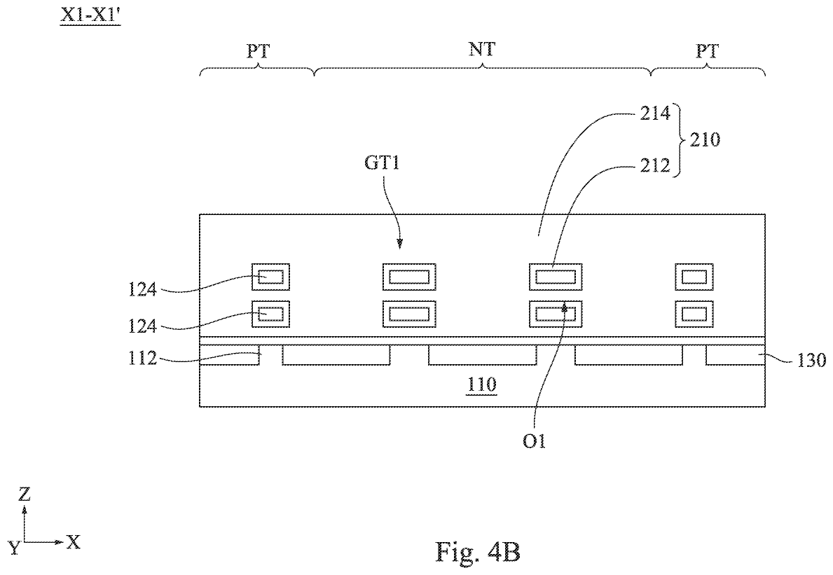

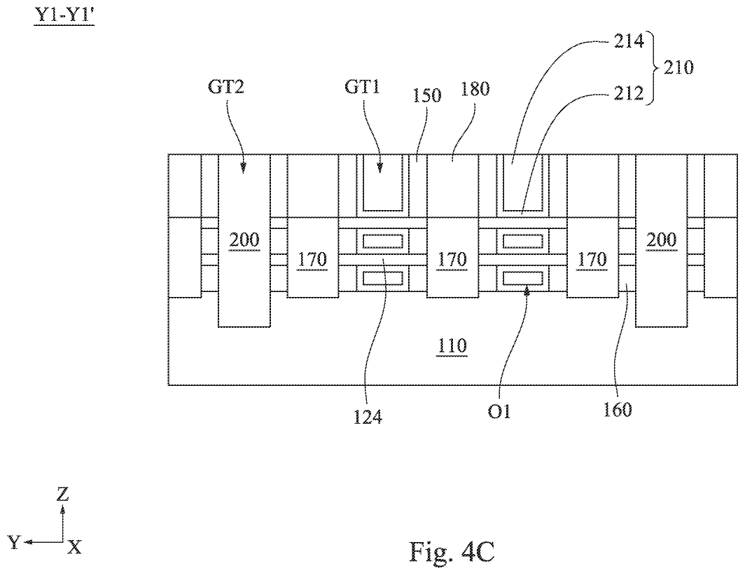

Reference is made to FIGS. 4A-4C. Some dummy gate structures 140 (referring to FIGS. 3A-3C) are replaced with metal gate structures 210. The metal gate replacement process may include removing a first group of the dummy gate structures 140 (referring to FIGS. 3A-3C), and removing the epitaxial layers 122 (referring to FIGS. 3B and 3C) therebelow. The removals form gate trenches GT1 between the gate spacers 150 and openings/spaces O1 between neighboring epitaxial layers 124. Replacement gate structures 210 are respectively formed in the gate trenches GT1 and openings/spaces O1 to surround each of the epitaxial layers 124 suspended in the gate trenches GT1. In some embodiments, the gate structure 210 can be interchangeably referred to a metal gate, a gate pattern, a gate strip, or a gate layer.

In the illustrated embodiments, the dummy gate structures 140 (referring to FIGS. 3A-3C) are removed by using a selective etching process (e.g., selective dry etching, selective wet etching, or a combination thereof) that etches the materials in dummy gate structures 140 (referring to FIGS. 3A-3C) at a faster etch rate than it etches other materials (e.g., gate spacers 150 and the dielectric material 180), thus resulting in gate trenches GT1 between corresponding gate spacers 150, with the top surface and sidewalls of the fins FS exposed in the gate trenches GT1. Subsequently, the epitaxial layers 122 in the gate trenches GT1 are etched by using another selective etching process that etches the epitaxial layers 122 at a faster etch rate than it etches the epitaxial layers 124, thus forming openings/spaces O1 between neighboring epitaxial layers 124. In this way, the epitaxial layers 124 become nanosheets suspended over the substrate 110 and between the source/drain epitaxial structures 170. This step is also called a channel release process. In some embodiments, the epitaxial layers 124 can be interchangeably referred to as nanowires, nanoslabs and nanorings, depending on their geometry. For example, in some other embodiments the epitaxial layers 124 may be trimmed to have a substantial rounded shape (i.e., cylindrical) due to the selective etching process for completely removing the epitaxial layers 122 (referring to FIGS. 3A-3C). In that case, the resultant epitaxial layers 124 can be called nanowires.

In some embodiments, the epitaxial layers 122 (referring to FIGS. 3A-3C) are removed by using a selective wet etching process. In some embodiments, the epitaxial layers 122 (referring to FIGS. 3A-3C) are SiGe and the epitaxial layers 124 are silicon allowing for the selective removal of the epitaxial layers 122. In some embodiments, the selective wet etching includes an APM etch (e.g., ammonia hydroxide-hydrogen peroxide-water mixture). In some embodiments, the selective removal includes SiGe oxidation followed by a SiGeOₓ removal. For example, the oxidation may be provided by O₃ clean and then SiGeOₓ removed by an etchant such as NH₄OH that selectively etches SiGeOₓ at a faster etch rate than it etches Si. Moreover, because oxidation rate of Si is much lower (sometimes 30 times lower) than oxidation rate of SiGe, the epitaxial layers 124 may remain substantially intact during the channel release process. In some embodiments, both the channel release step and the previous step of laterally recessing sacrificial layers use a selective etching process that etches SiGe at a faster etch rate than etching Si, and therefore these two steps may use the same etchant chemistry in some embodiments. In this case, the etching time/duration of channel release step is longer than the etching time/duration of the previous step of laterally recessing sacrificial layers, so as to completely remove the sacrificial SiGe layers.

Therefore, the gate structures 210 of final gates of GAA FETs can be formed. The final gate structure may be a high-k/metal gate stack, however other compositions are possible. In some embodiments, each of the gate structures 210 forms the gate associated with the multi-channels provided by the plurality of epitaxial layers 124. For example, high-k/metal gate structures 210 are formed within the openings O1 provided by the release of epitaxial layers 124. In various embodiments, the high-k/metal gate structure 210 includes a gate dielectric layer 212 around the epitaxial layers 124 and a gate metal layer 214 formed around the gate dielectric layer 212 and filling a remainder of gate trenches GT1. Formation of the high-k/metal gate structures 210 may include one or more deposition processes to form various gate materials, followed by a CMP processes to remove excessive gate materials.

In some embodiments, the gate dielectric layer 212 includes an interfacial layer formed around the epitaxial layers 124 and a high-k gate dielectric layer formed around the interfacial layer. The interfacial layer may be silicon oxide formed on exposed surfaces of semiconductor materials in the gate trenches GT1 by using, for example, thermal oxidation, chemical oxidation, wet oxidation or the like. As a result, surface portions of the epitaxial layers 124 and the substrate 110 exposed in the gate trenches GT1 are oxidized into silicon oxide to form interfacial layer. In some embodiments, the high-k gate dielectric layer includes dielectric materials such as hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), the like, or combinations thereof.

In some embodiments, the gate metal layer 214 includes one or more metal layers. For example, the gate metal layer 214 may include one or more work function metal layers stacked one over another and a fill metal filling up a remainder of gate trenches GT1. The one or more work function metal layers in the gate metal layer 214 provide a suitable work function for the high-k/metal gate structures 210. The work function metal layers may include TIN, TaN, TiAl, TiAlN, TaAl, TaAlN, TaAlC, TaCN, WNC, Co, Ni, Pt, W, or combination thereof. NMOSFET and PMOSFET may include the same work function material, or different work function materials. For example, n-type work function metals in the second conductivity type device region NT for NMOSFET may exemplarily include, but are not limited to, titanium aluminide (TiAl), titanium aluminium nitride (TiAIN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TIC), aluminum carbide (AIC)), aluminides, and/or other suitable materials. P-type work function metal in the first conductivity type device region PT for PMOSFET may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. In some embodiments, the fill metal in the gate metal layer 214 may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials. One for more lithography and patterning processes may be performed for forming the work-function metals for NMOSFET and forming the work-function metals for PMOSFET.

In some embodiments, before or after replacing the first group of the dummy gate structures 140 with the metal gate structures 210, a second group of dummy gate structures 140 is replaced with isolation structures 200, which may also be referred to as dielectric gates. The dielectric gate replacement process may include removing the second group of the dummy gate structures 140 (referring to FIGS. 3A-3C), and removing the epitaxial layers 122 and epitaxial layers 124 (referring to FIGS. 3B and 3C) therebelow. The removals form gate trenches GT2 between the gate spacers 150 and between the inner spacers 160. The isolation structures 200 are respectively formed in the gate trenches GT2. In some embodiments, the pull-up transistors PU1 and PU2 are situated between the isolation structures 200. In some embodiments, the isolation structures 200 includes suitable dielectric materials, such as silicon oxide (SiO₂), a silicon nitride (SiN), a silicon carbide (SiC), a silicon oxynitride (SiON), other suitable materials, and/or combinations thereof. The dielectric material may be deposited by a PECVD process or other suitable deposition technique. After depositing the dielectric material, a planarization process may be performed to remove excessive materials of the dielectric material. For example, a planarization process includes a chemical mechanical planarization (CMP) process which removes portions of the dielectric material 180 overlying gate structures 140/210 and planarizes a top surface of the integrated circuit structure. In some embodiments, the isolation structure 200 can be interchangeably referred to as an isolation line pattern, an isolation strip, a dielectric strip, or a dielectric gate structure.

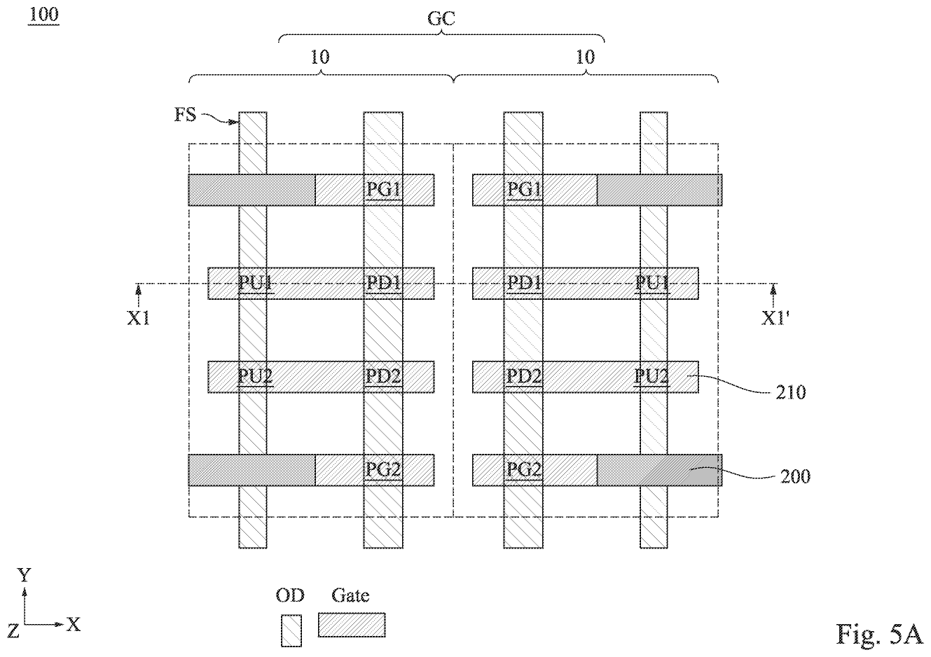

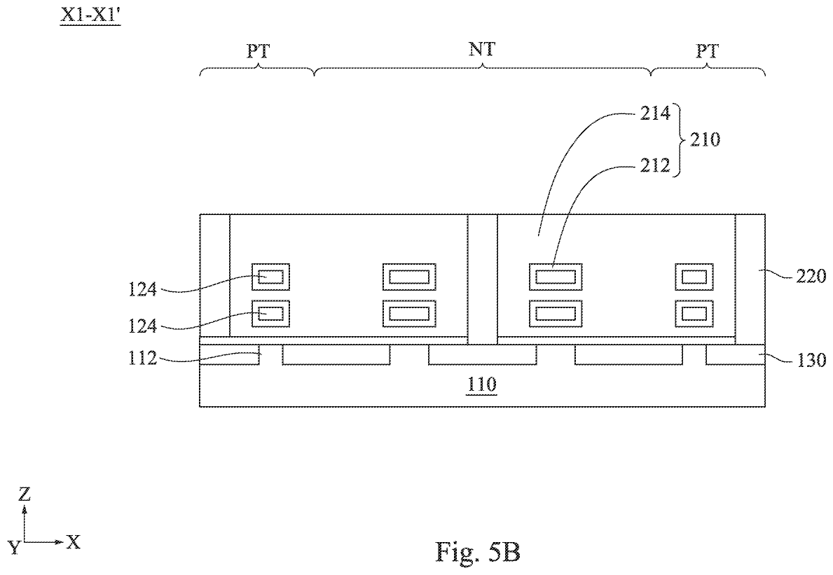

Reference is made to FIGS. 5A and 5B. A gate end dielectric 220 may either be disposed between gate structures 210, at an end of a gate structure 210 after a gate cut process, between isolation structures (or dielectric gates) 200, at an end of an isolation structure (or dielectric gate) 200 after a gate cut process. In some embodiments, the gate end dielectric 220 may be referred to as dielectric plugs. The gate end dielectric layer 220 may include suitable dielectric materials, such as oxide, Si₃N₄, other nitride-base dielectric, carbon-base dielectric, high k material (e.g., having a k value equal to or greater than 9), or other suitable dielectric material. Formation of the gate end dielectric 220 may include etching away portions of the metal gate structures 210 and the isolation structures (or the dielectric gates) 200 to expose underlying dielectric materials (e.g., the isolation structures 130), and depositing the suitable gate end dielectric materials over the underlying dielectric materials (e.g., the isolation structures 130). A CMP process may be performed to remove excess portions of the gate end dielectric materials, leaving the remaining portions forming the gate end dielectric 220. Through the configuration, the gate end dielectric 220 and the isolation structures (or the dielectric gates) 200 are located at boundaries of the cells 10 for isolation purposes.

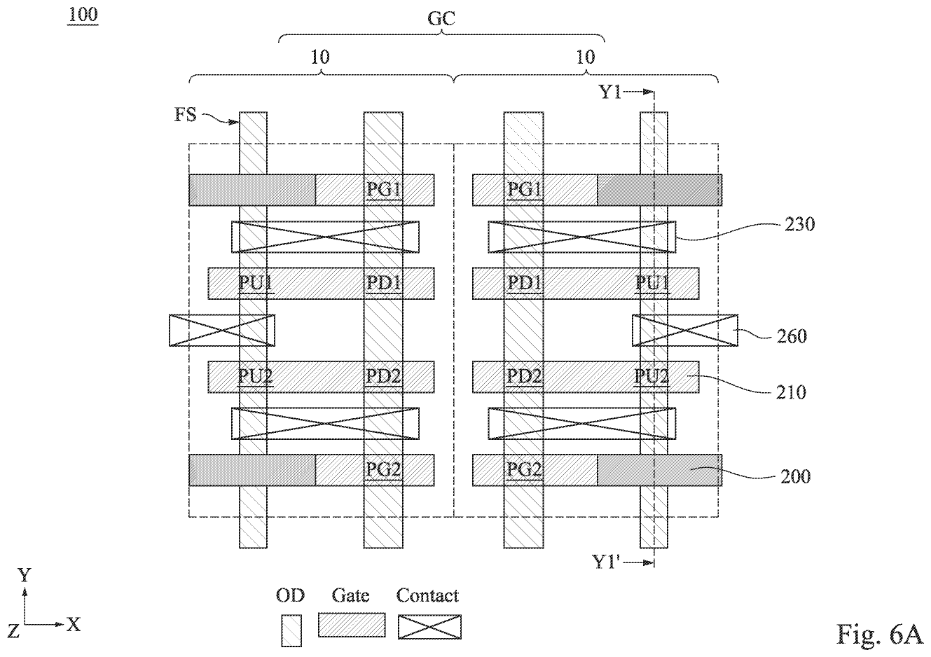

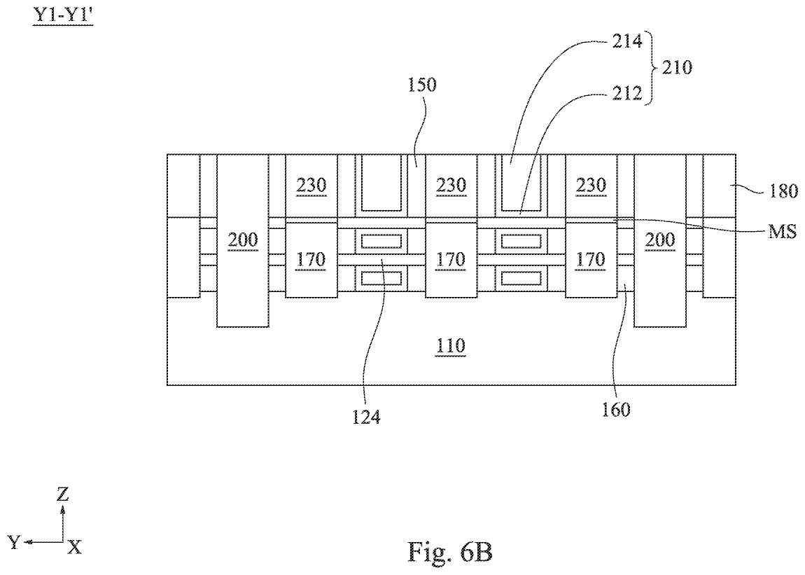

Reference is made to FIGS. 6A and 6B. Source/drain contacts 230 are formed over the source/drain epitaxial structures 170. In some embodiments, the formation of the source/drain contacts 230 includes etching source/drain contact openings through the dielectric material 180 to expose top surfaces of the source/drain epitaxial structures 170, and depositing one or more metal materials into the source/drain contact openings. The metal materials may include W, Ru, Co, Cu, Ti, TiN, Ta, TaN, Mo, Ni, Pt, Ir, Rh, the like or combinations thereof. The metal materials are deposited to fill the source/drain contact openings by using suitable deposition techniques (e.g., CVD, PVD, ALD, the like or combinations thereof). Subsequently, a CMP process can be performed to remove excess metal materials outside the source/drain contact openings, while leaving metal materials in the source/drain contact openings to serve as the source/drain contacts 230. The source/drain contacts 230 may include a single metal material or multiple metal material layers. The source/drain contacts 230 may be isolated from the gate structure 210 by the gate spacers 150 and the inner spacer 160. In some embodiments, from the layout top view as shown in FIG. 6A, the source/drain contacts 230 may be elongated. For example, and the dimension of a longer side of the source/drain contacts 230 is greater than the dimension of a short side of the source/drain contacts 230.

In some embodiments, prior to depositing the metal materials of the source/drain contacts 230, metal silicide regions MS may be formed on exposed top surfaces of the source/drain epitaxial structures 170 by using a silicidation process. Silicidation may be formed by blanket depositing a metal layer over the exposed source/drain epitaxial structures 170, annealing the metal layer such that the metal layer reacts with silicon (and germanium if present) in the source/drain epitaxial structures 170 to form the metal silicide regions MS, and thereafter removing the non-reacted metal layer. In some embodiments, the metal layer used in the silicidation process includes nickel, cobalt, titanium, tantalum, platinum, tungsten, other noble metals, other refractory metals, rare earth metals or their alloys. Thus, metal silicide regions MS may be between the source/drain contacts 230 and the source/drain epitaxial structure 170.

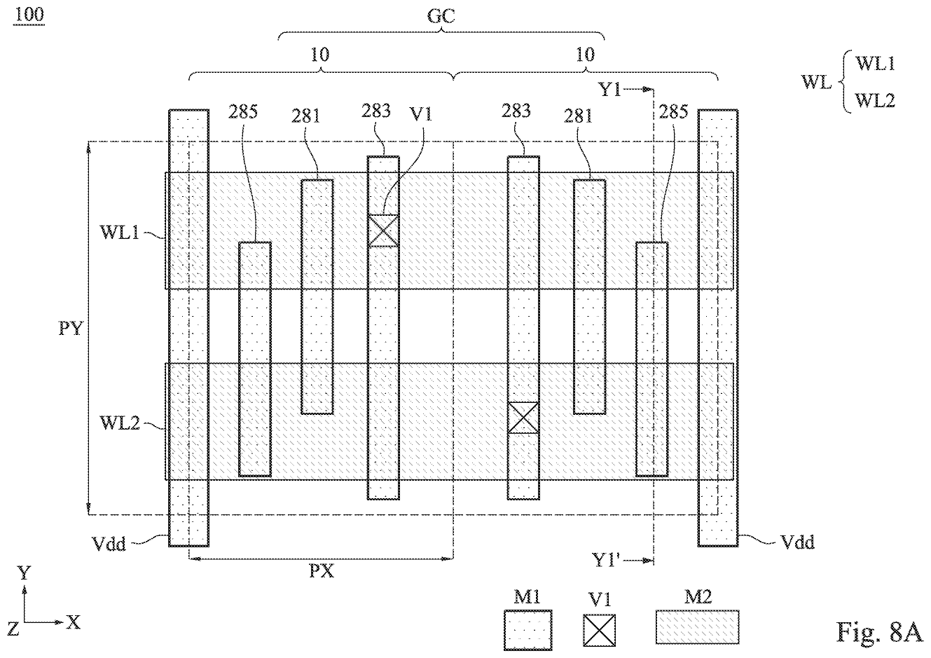

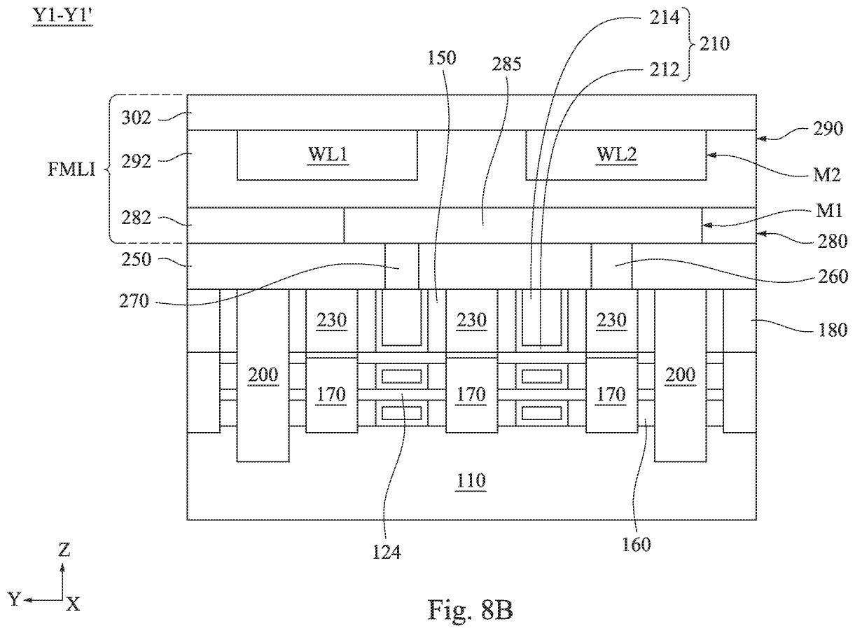

Reference is made to FIGS. 7A-8B. Source drain vias 260 and gate vias 270 can be formed over the source/drain contacts 230 and the high-k/metal gate structures 210, respectively (see FIGS. 7A-8C). Subsequently, a front-side multilayer interconnection (MLI) structure FMLI can be formed over the substrate 110 (see FIGS. 7A-8B).

Specifically, as shown in FIGS. 7A-7C, formation of the source drain vias 260 and/or the gate vias 270 may include etching an opening in a dielectric layer 250 deposited over the source/drain contacts 230 and the high-k/metal gate structures 210, etching one openings in the dielectric layer 250, and depositing conductive materials into the openings in the dielectric layer 250. A CMP process may be performed to remove excess portions of the conductive materials outside the openings in the dielectric layer 250.

As shown in FIGS. 7A-8B, the front-side MLI structure FMLI may include at least three front-side metallization layers. The number of front-side metallization layers may vary according to design specifications of the integrated circuit structure. Only two front-side metallization layers 280 and 290 are illustrated herein for the sake of simplicity. The front-side metallization layers each comprise one or more front-side inter-metal dielectric (IMD) layers (e.g., IMD layers 282, 292, 302 as shown in FIG. 8B), one or more horizontal interconnects respectively extending horizontally in the IMD layers, and one or more vertical interconnects respectively extending vertically in the IMD layers. For example, the front-side metallization layer 280/290 comprises IMD layers 282/292, horizontal interconnects (e.g., metal lines M1/M2) and vertical interconnects (e.g., metal via VI as shown in FIG. 8A). The metal via VI (see FIG. 8A) connects the metal lines M1 to the metal lines M2. In some embodiments, a routing direction of the metal lines M1 is different from or perpendicular to a routing direction of the metal lines M2. For example, the metal lines M2 extends along the direction X, and the metal line M1 extends along the direction Y. In some embodiments, the metal line M1/M2 can be interchangeably referred to as a metal track.

The front-side metallization layers 280 may be referred to as a lowest metallization layer. The metal lines M1 of the lowest metallization layer 280 of the front-side MLI structure FMLI may include high power rails Vdd (see FIGS. 7A and 7B). The high power rails Vdd may be electrically coupled to the positive power supply node CVdd, as shown in FIG. 1A, such that a power electrical connection can be established from the metal lines M1 (e.g., the high power rails Vdd) to the source/drain epitaxial structure 170. In some embodiments, the high power rails Vdd are located at cell boundaries and shared with one of adjacent cells, and electrically connected to the source nodes of transistors PU1 and PU2. In some embodiments, the power rail Vdd can be interchangeably referred to as a power supply voltage line or a power mesh conductor.

In some embodiments, a conductive path between source/drain epitaxial structure 170 and the high-k/metal gate structure 210 can be established by some metal lines M1. Specifically, the metal lines M1 of the lowest metallization layer 280 of the front-side MLI structure FMLI may include local interconnects 281 and 282. The local interconnect 281 can build an electrically connection between the source/drain contact 230 and the gate structures 210 of the transistors PD2 and PU2, and the local interconnect 281 can build an electrically connection between the source/drain contact 230 and the gate structures 210 of the transistors PD1 and PU1. In some embodiments, the local interconnects 281 and 282 can be interchangeably referred to as local interconnect conductors, local connection lines, or metal lines. In some embodiments, metal lines M1 of the lowest metallization layer 280 of the front-side MLI structure FMLI may include word line landing pad 283 connecting the gate structures 210 of the transistors PG1 and PG2 to the word lines WL1 and WL2.

The metal lines M2 of the metallization layer 290 (see FIGS. 8A and 8B) of the front-side MLI structure FMLI may include word lines WL1 and WL2 (see FIGS. 8A and 8B). The word lines WL1 and WL2 may be electrically coupled to the gate structures 210 of the pass-gate transistors PG1 and PG2 through the metal line M1. In some embodiments, the word lines WL1 and WL2 can be interchangeably referred to as word line conductors.

In some embodiments, the metallization layers M1 and M2 can be formed using, for example, a single damascene process, a dual damascene process, the like, or combinations thereof. In some embodiments, the IMD layers 282, 292, 302 may include low-k dielectric materials having k values, for example, lower than about 4.0 or even 2.0 disposed between such conductive features. In some embodiments, the IMD layers 282, 292, 302 may be made of, for example, phosphosilicate glass (PSG), borophosphosilicate glass (BPSG), fluorosilicate glass (FSG), SiOₓC_{y}, Spin-On-Glass, Spin-On-Polymers, silicon oxide, silicon oxynitride, combinations thereof, or the like, formed by any suitable method, such as spin-on coating, chemical vapor deposition (CVD), plasma-enhanced CVD (PECVD), or the like. The front-side metal lines and vias M1, M2, and VI may comprise metal materials such as W, Ru, Co, Cu, Ti, TIN, Ta, TaN, Mo, Ni, combinations thereof, or the like. In some embodiments, the front-side metal lines and vias M1, M2, and VI may further comprise one or more barrier/adhesion layers (not shown) to protect the respective front-side IMD layers 282 and 292 from metal diffusion (e.g., copper diffusion) and metallic poisoning. The one or more barrier/adhesion layers may comprise titanium, titanium nitride, tantalum, tantalum nitride, or the like, and may be formed using physical vapor deposition (PVD), CVD, ALD, or the like.

Reference is made to FIGS. 9A-10B. A back-side dielectric layer 310 is deposited over the back sides of the devices, and back-side source/drain contacts 320 are formed in the back-side dielectric layer 310 and over back sides of source/drain epitaxial structures 170 (see FIGS. 9A-9E). Subsequently, a back-side multilayer interconnection (MLI) structure BMLI including plural back-side metallization layers can be formed over the substrate 110 (see FIGS. 9A-10B).

Specifically, as shown in FIGS. 9A-9E, one or more processes are performed to remove materials at the back sides of source/drain epitaxial structures 170, thereby exposing the back sides of source/drain epitaxial structures 170. For example, a planarization process (e.g., a CMP process, or a grinding process) is performed to thinning down the substrate 110 (referring to FIGS. 8A and 8B). The planarization process may also remove portions of or all the isolation structures 130 (referring to FIG. 7B). In some embodiments, after the planarization process, one or more etching process may be performed to remove the substrate 110 and the isolation structures 130 (referring to FIGS. 7B, 8A, and 8B). In some alternative embodiments, portions of the isolation structures 130 (referring to FIG. 7B) may remain at back sides of the devices.

Subsequently, the back-side dielectric layer 310 is deposited over the back sides of the devices, e.g., the back sides of the source/drain epitaxial structures 170 and the back sides of the high-k/metal gate structures 210. In some embodiments, the back-side dielectric layer 310 may include, for example, a low-k dielectric material (with dielectric constant lower than about 7) such as SiO₂, SiN, SiCN, SiOC, SiOCN, the like, or combinations thereof. In some embodiments, the back-side dielectric layer 310 includes a high-k dielectric material such as HfO₂, ZrO₂, HfAlOₓ, HfSiOₓ and Al₂O₃, the like or combinations thereof. A CMP process is may be performed on the back-side dielectric layer 310.

Subsequently, the source/drain contacts 320 are formed over the back sides of the source/drain epitaxial structures 170. In some embodiments, the source/drain contacts 320 can be interchangeably referred to as back-side contacts. In some embodiments, the source/drain contacts 320 can be a longer contact to connect both pass-gate drain nodes of adjacent cells in word line routing direction. In some embodiments, the source/drain contacts 320 can extend to overlap the low power rail Vss1, the bit line BL, and the bit line bar BLB in the lengthwise direction of the gate structure 210 from the top view. The source/drain contacts 320 can have a lateral dimension D1 (see FIG. 9A) extending along a lengthwise direction of the gate structure 210 (e.g., X-direction), and a lateral dimension D2 (see FIG. 9A) extending along a lengthwise direction of the fin FS (e.g., Y-direction). In some embodiments, the lateral dimension D1 is greater than the lateral dimension D2. By way of example and not limitation, a dimension ratio of the lateral dimension D1 to the lateral dimension D2 may be in a range from about 1.1 to about 15, such as about 1.1, 1.5, 2, 3, 4, 5, 6, 7, 8, 9, 10, 11, 12, 13, 14, or 15. In some embodiments, the formation of the source/drain contacts 320 includes etching source/drain contact openings through the back-side dielectric layer 310 to expose back sides of the source/drain epitaxial structures 170, and depositing one or more metal materials into the source/drain contact openings. The metal materials may include W, Ru, Co, Cu, Ti, TiN, Ta, TaN, Mo, Ni, the like or combinations thereof. The metal materials are deposited to fill the source/drain contact openings by using suitable deposition techniques (e.g., CVD, PVD, ALD, the like or combinations thereof). Subsequently, a CMP process can be performed to remove excess metal materials outside the source/drain contact openings, while leaving metal materials in the source/drain contact openings to serve as the source/drain contacts 320. In some embodiments, prior to depositing the metal materials, metal silicide regions may be formed on exposed back sides of the source/drain epitaxial structures 170 by using a silicidation process.

As shown in FIGS. 9A-10B, the back-side multilayer interconnection (MLI) structure BMLI can be formed over the substrate 110. The number of back-side metallization layers may vary according to design specifications of the integrated circuit structure. Only two back-side metallization layers (e.g., the metallization layers 330 and 340) are illustrated for the sake of simplicity. The back-side metallization layers each comprise one or more back-side inter-metal dielectric (IMD) layers, one or more horizontal interconnects respectively extending horizontally in the IMD layers, and one or more vertical interconnects respectively extending vertically in the IMD layers. For example, the back-side metallization layer 330/340 comprises IMD layers 332/334/342, horizontal interconnects (e.g., metal lines BM1/BM2) and vertical interconnects (e.g., metal via BV0/BV1). The metal via BV0 may connect the source/drain contacts 320 to the metal lines BM1, and the metal via BV1 may connect the metal lines BM1 to the metal lines BM2. In some embodiments, a routing direction of the metal lines BM1 is different from or perpendicular to a routing direction of the metal lines BM2. For example, the metal lines BM2 extends along the direction X, and the metal line BM1 extends along the direction Y.

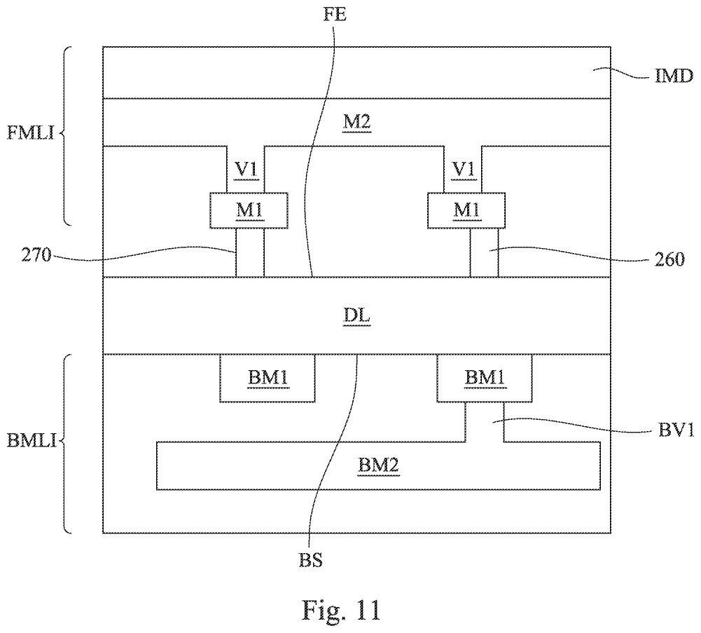

The metal lines BM1 of the metallization layer 330 may include low power rails Vss1, bit lines BL, and bit line bars BLB, such that the low power rails Vss1, the bit lines BL, and the bit line bars BLB can be positioned at a same level height on the back side BS (see FIG. 11) of the integrated circuit structure 100. In some embodiments, the low power rail Vss1 can be laterally situated between the bit line BL and the bit line bar BLB. The low power rails Vss1, bit lines BL, and bit line bars BLB can extend in parallel with each other. In some embodiments, the power rail Vss can be interchangeably referred to as a power supply voltage line or a power mesh conductor. In some embodiments, the front-side MLI structure FMLI can be free of the low power rails Vss1, the bit lines BL, and the bit line bars BLB.

The low power rails Vss1 can land on the metal via BV0 (see FIGS. 9A and 9B) over the source/drain contact 320 connecting the epitaxial structures 170 of the pull-down transistors PD1 and PD2 in different SRAM cells 10, such that a power electrical connection can be established from the metal lines BM1 and BM2 (e.g., the high power rails Vss1 and Vss2) to the source/drain epitaxial structures 170. In some embodiments, the low power rails Vss1 (see FIG. 9A) non-overlaps the high power rails Vdd (see FIG. 7A). In some embodiments, the low power rail Vss1 non-overlaps the transistors PG1, PG2, PD1, PD2, PU1, and PU2. In some embodiments, the low power rails Vss1 can be interchangeably referred to as a power line, power conductor, a conductive line, a metal line, or a metal layer.

The bit line BL can land on the metal via BV0 (see FIGS. 9A and 9C) over the source/drain contact 320 connecting the epitaxial structures 170 of the pass-gate transistors PG1 in different SRAM cells 10, and the bit line bar BLB can land on the metal via BV0 (see FIGS. 9A and 9D) over the source/drain contact 320 connecting the epitaxial structures 170 of the pass-gate transistors PG2 in different SRAM cells 10. In other words, the bit lines BL and the bit line bars BLB are of the back-side MLI structure BMLI. Therefore, signal electrical connections can be established from the metal lines BM1 (e.g., bit line BL and bit line bars BLB) to the source/drain epitaxial structure 170. In some other embodiments, while each of groups of two adjacent cells 10 may share one bit line BL and one bit line bar BLB that are of the back-side MLI structure BMLI, some bit lines BL and some bit line bars BLB are of the front-side MLI structure FMLI, and the other bit lines BL and the other bit line bars BLB are of the back-side MLI structure BMLI. In some embodiments, the bit line BL and the bit line bar BLB extend in a direction perpendicular to a lengthwise direction of the gate structure 210. In some embodiments, the bit line BL and the bit line bar BLB extend in a direction perpendicular to a lengthwise direction of the word line WL1/WL2. In some embodiments, a lateral dimension D3 (e.g., width) of the bit line BL can be greater than a lateral dimension D4 (e.g., width) of the low power rail Vss1, and a lateral dimension D5 (e.g., width) of the bit line bar BLB can be greater than the lateral dimension D4 (e.g., width) of the low power rail Vss1 in the lengthwise direction of the gate structure 210. In some embodiments, the bit line BL can be interchangeably referred to as a bit line conductor, and the bit line bar BLB can be interchangeably referred to as a bit line bar conductor.

Therefore, the low power rail Vss1, the bit lines BL, and the bit line bars BLB are situated at the back-side of the wafer, which in turn reduces routing load and facilitates reduction in cell size. Having fewer metal tracks within the same layer can enhance the metal conductor's RC (resistance-capacitance) performance. This results in both lower resistance, due to increased metal width, and reduced capacitance, achieved by creating larger spaces between metal tracks. Specifically, the capacitance of the bit-line can include three components: the metal-BL in the Back-End-Of-Line (BEOL), the contact to gate in the Middle-End-Of-Line (MEOL: CCO), and the source/drain (S/D) to gate in the Front-End-Of-Line (FEOL). By moving the bit lines BL and the bit line bars BLB to the back-side of the devices, the MEOL capacitance can be reduced. This reduction can be achieved by minimizing the overlap area between the contact and the gate, while also benefiting from the lowest BEOL resistance and capacitance due to increased metal width and space. Additionally, the word-line routing and pass gate device strap settings can organize horizontal cells into groups to two rows. By merging two cells 10 with a single bit-line pair (i.e., bit line BL and bit line bar BLB), an additional space for the bit line BL and the bit line bar BLB can be created, allowing for either wider bit line/bit line bar width in larger arrays (with more columns and rows), increased metal spacing to reduce capacitance.

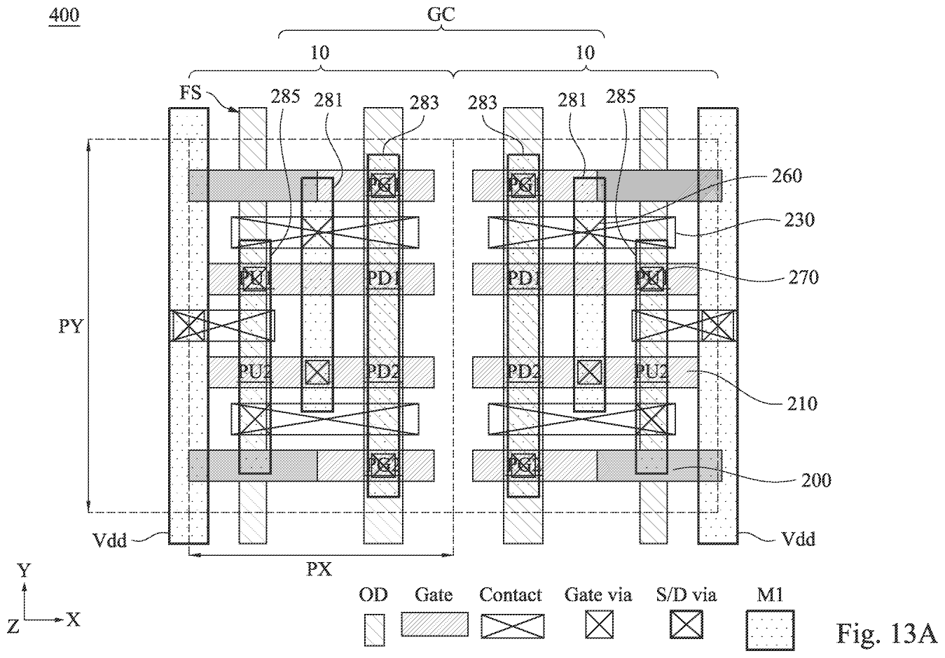

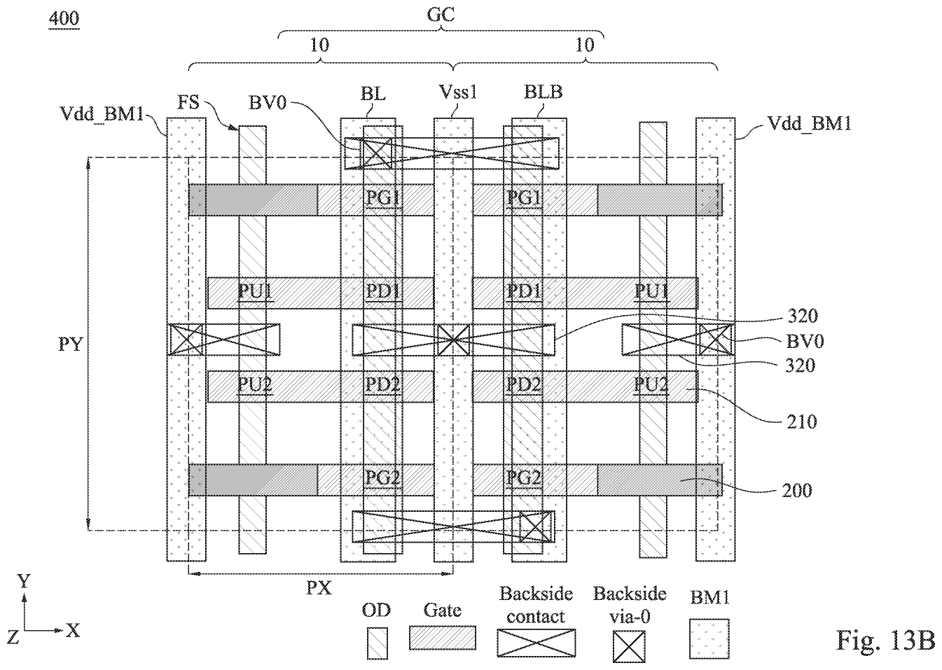

In some embodiments, additional high power rails Vdd can be formed in the metallization layer 330 (see FIG. 13B). As shown in FIGS. 10A and 10B, the metal lines BM2 of the metallization layer 340 may include a bus low power rail Vss2. The bus low power rail Vss2 can be electrically coupled to a power supply voltage node CVss as shown in FIG. 1A, and electrically connected to the high power rail Vss1 through the metal via BV1.

The metallization layers 330 and 340 can be formed using, for example, a single damascene process, a dual damascene process, the like, or combinations thereof. In some embodiments, the IMD layers 332, 334, and 342 may include low-k dielectric materials having k values, for example, lower than about 4.0 or even 2.0 disposed between such conductive features. In some embodiments, the IMD layers 332, 334, and 342 may be made of, for example, phosphosilicate glass (PSG), borophosphosilicate glass (BPSG), fluorosilicate glass (FSG), SiOₓC_{y}, Spin-On-Glass, Spin-On-Polymers, silicon oxide, silicon oxynitride, combinations thereof, or the like, formed by any suitable method, such as spin-on coating, chemical vapor deposition (CVD), plasma-enhanced CVD (PECVD), or the like. The back-side metal lines and vias BM1, BM2, BV0, and BV1 may comprise metal materials such as W, Ru, Co, Cu, Ti, TiN, Ta, TaN, Mo, Ni, combinations thereof, or the like. In some embodiments, the back-side metal lines and vias BM1, BM2, BV0, and BV1 may further comprise one or more barrier/adhesion layers (not shown) to protect the respective back-side IMD layers 332, 334, and 342 from metal diffusion (e.g., copper diffusion) and metallic poisoning. The one or more barrier/adhesion layers may comprise titanium, titanium nitride, tantalum, tantalum nitride, or the like, and may be formed using physical vapor deposition (PVD), CVD, ALD, or the like.

As shown in the front-side layout of FIG. 7A and the back-side layout of FIG. 9A, the standard cell 10 is formed as a SRAM cell. For example, the transistor PD1 and the transistor PU1 share a continuous gate structure 210, the transistor PD2 and the transistor PU2 share a continuous gate structure 210. For power routing, nodes of the transistors PU1 and PU2 are electrically connected to the front-side power rails Vdd, nodes of the transistors PD1 and PD2 are electrically connected to the back-side power rail Vss1. For signal routing, a node of the transistor PG1 is electrically connected to the back-side bit line BL, and a node of the transistor PG2 is electrically connected to the back-side bit line bar BLB. Two adjacent tall SRAM cells 10 may share one back-side bit line BL and one back-side bit line bar BLB for benefiting the metal conductor RC performance.

As shown in the front-side layout of FIG. 7A and the back-side layout of FIG. 9A, the SRAM cell 10 can be a tall cell structure. For example, the SRAM 10 can have a pitch (i.e., first dimension) Px in the direction X and a pitch Py (i.e., second dimension) in the direction Y, and the pitch Px is shorted than the pitch Py for arranging two active regions and four gate lines into one cell 10. For example, the pitch Py is about 4 times the gate pitch, each gate pitch can be defined between two adjacent gate lines. In some embodiments, the pitch Px may correspond to widths of bit lines BL and bit line bars BLB, and the pitch Py may correspond to widths of word lines WL1 and WL2. Therefore, the tall SRAM cell structure can use less OD lines (lower down to 2 groups) and first metal line metal tracks (lower down to 4) to finish cell connections, thereby achieving highly capability for cell scaling. By way of example and not limitation, a dimension ratio of the pitch Py to the pitch Px may be in a range from about 1.2 to about 2.5, such as about 1.2, 1.4, 1.6, 1.8, 2.0, 2.2, 2.4, or 2.5.

Reference is made to FIG. 11. FIG. 11 is a cross-sectional views of an integrated circuit chip according to some embodiments of the present disclosure. The devices PG1, PG2, PU1, PU2, PD1, and PD2 in FIGS. 7A and 9A are illustrated as the device layer DL in FIG. 11. The front-side interconnect structure FMLI and the back-side interconnect structure BMLI are respectively at a front side FE of the device layer DL and at a back side BS of the device layer DL. The front-side interconnect structure FMLI is connected to the device layer DL through the via layer (e.g., source drain vias 260 and gate vias 270). In some embodiments of the present disclosure, for the signal routing, one of the front-side interconnect structure FMLI and the back-side interconnect structure BMLI comprises one of the bit line BL and the bit line bar BLB (referring to FIGS. 1A and 1B), while another one of the front-side interconnect structure FMLI and the back-side interconnect structure BMLI comprises another one of the bit line BL and the bit line bar BLB (referring to FIGS. 1A and 1B).

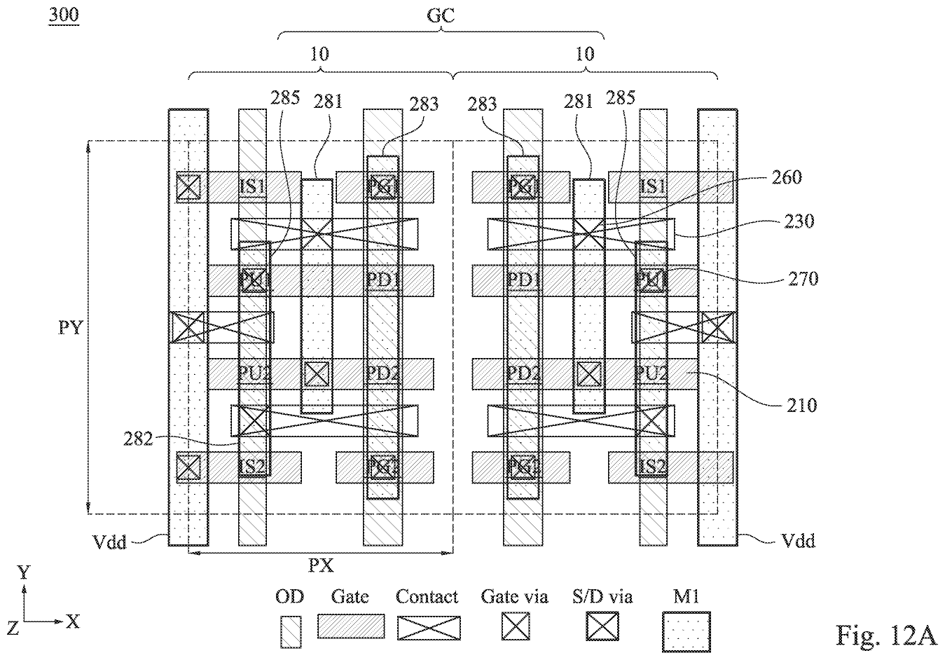

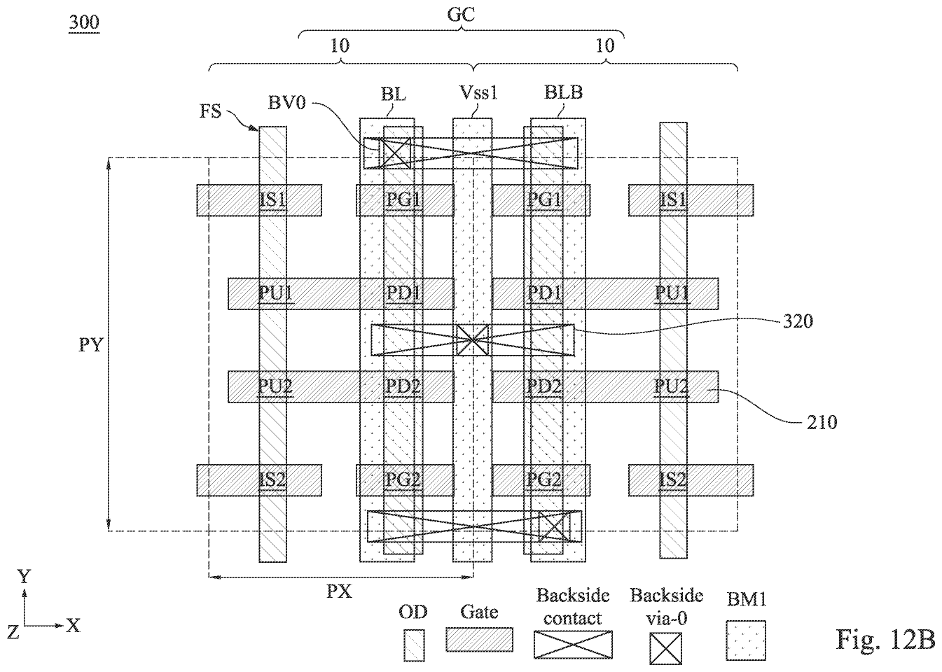

Reference is made to FIGS. 12A and 12B. FIGS. 12A and 12B illustrate front-side and back-side layouts of an integrated circuit structure according to some embodiments of the present disclosure. While FIGS. 12A and 12B show an embodiment of the integrated circuit structure 300 with different layout profiles than the integrated circuit structure 100 in FIGS. 2-10B, the present disclosure may repeat reference numerals and/or letters in the various examples. This repetition is for the purpose of simplicity and clarity and does not in itself dictate a relationship between the various embodiments and/or configurations discussed. The difference between the embodiment in FIGS. 12A and 12B and the embodiment in FIGS. 2-10B is in that the isolation structures 200 shown in FIGS. 2-10B (or dielectric gates) can be omitted from the integrated circuit structure 300. Instead, gate end dielectric 220 may be formed to cut the gate structures 210. As result, isolation devices IS1 and IS2 that are electrically disconnected from elements of the SRAM cells 10 are formed. The gate nodes of the isolation devices IS1 and IS2 can be electrically connected to the high power rails Vdd. Other details of the present embodiments are similar to those illustrated above, not repeated herein. In some embodiments, the isolation devices IS1 and IS2 can be interchangeably referred to as dummy transistors.

Reference is made to FIGS. 13A and 13B. FIGS. 13A and 13B illustrate front-side and back-side layouts of an integrated circuit structure 400 according to some embodiments of the present disclosure. While FIGS. 13A and 13B show an embodiment of the integrated circuit structure 400 with different layout profiles than the integrated circuit structure 100 in FIGS. 2-10B, the present disclosure may repeat reference numerals and/or letters in the various examples. This repetition is for the purpose of simplicity and clarity and does not in itself dictate a relationship between the various embodiments and/or configurations discussed. The difference between the embodiment in FIGS. 13A and 13B and the embodiment in FIGS. 2-10B is in that the integrated circuit structure 400 can have additional high power rails Vdd_BM1 of the metal lines BM1 in the metallization layer 330. The high power rails Vdd_BM1 can land on the metal via BV0 (see FIG. 13B) over the source/drain contact 320 connecting the epitaxial structures 170 of the pull-up transistors PU1 and PU2 in the SRAM cell 10, such that a power electrical connection can be established from the metal line BM1 to the source/drain epitaxial structures 170.

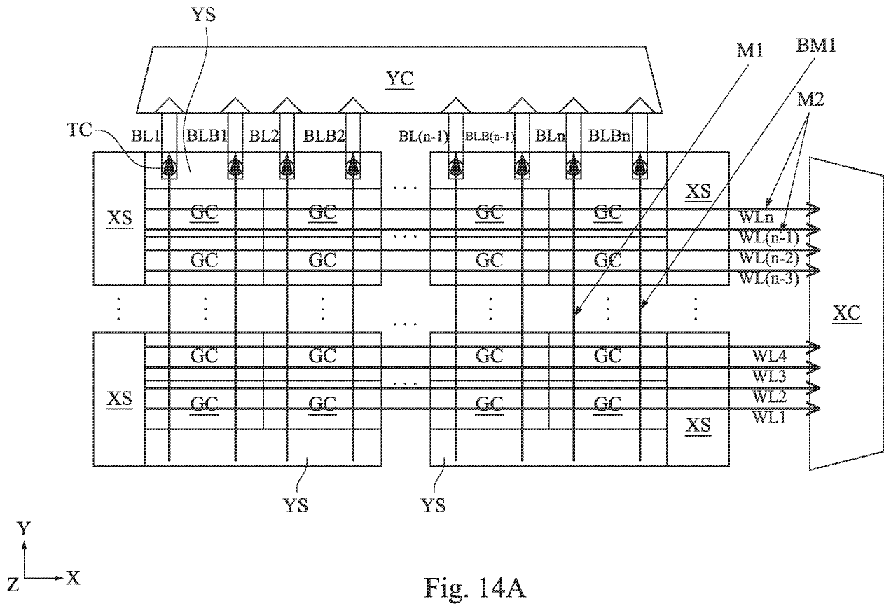

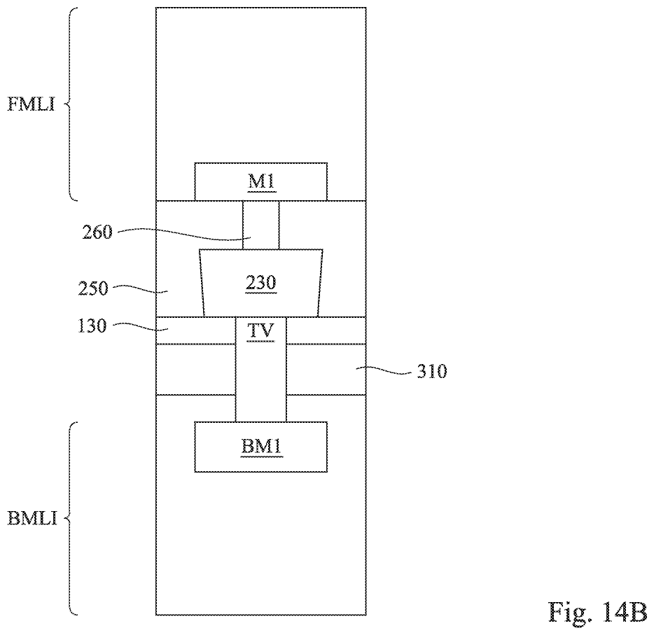

Reference is made to FIGS. 14A and 14B. FIG. 14A illustrates a block diagram of an integrated circuit structure according to some embodiments of the present disclosure. FIG. 14B is a cross-sectional view of a tap structure of the integrated circuit chip of FIG. 14A. The SRAM array includes groups GC of SRAM cell. Bit lines BL1-BLn and bit line bars BLB1-BLBn may be electrically coupled between the groups GC of SRAM cell and a column circuit YC. Word lines WL1-WLn may be electrically coupled between the groups GC of SRAM cell and a row circuit XC. The column circuit YC may include write drivers, multiplexers, sense amplifier, the like, or the combination thereof. Plural tap cells TC may be formed at row edge regions XC and column edge regions YS of the SRAM array. Each of the tap cells TC may include a tap structure for routing front-side metal lines and back-side metal lines. For example, in the column edge regions YS, the tap structure includes a tap via TV, an elongated contact 230, and a via 260 to make an electrically connection between a front-side metal line M1 and a back-side metal line BM1, thereby routing the bit line bar BLB from the front-side metal line M1 to the backside back-side metal line BM1. The tap via TV may extend through the isolation structures 130 and the back-side dielectric layer 310.

Therefore, based on the above discussions, it can be seen that the present disclosure offers advantages. It is understood, however, that other embodiments may offer additional advantages, and not all advantages are necessarily disclosed herein, and that no particular advantage is required for all embodiments. The present disclosure in various embodiments provides a method to position the low power rail Vss1, the bit lines BL, and the bit line bars BLB at the back-side of the wafer, which in turn reduces routing load and facilitates reduction in cell size. Having fewer metal tracks within the same layer can enhance the metal conductor's RC (resistance-capacitance) performance. This results in both lower resistance, due to increased metal width, and reduced capacitance, achieved by creating larger spaces between metal tracks. Additionally, the word-line routing and pass gate device strap settings can organize horizontal cells into groups to two rows. By merging two cells with a single bit-line pair (e.g., bit line and bit line bar), an additional space for the bit line and the bit line bar can be created, allowing for either wider bit line/bit line bar width in larger arrays (with more columns and rows), increased metal spacing to reduce capacitance.

In some embodiments of the present disclosure, a method includes forming a static random access memory (SRAM) array in a device layer, wherein the SRAM array comprises a first SRAM cell and a second SRAM cell adjacent to the first SRAM cell, and from a top view, the first and second SRAM cells are arranged in a first direction; forming first and second word lines over a front-side of the device layer extending across the first and second SRAM cells in the first direction, wherein the first word line is electrically coupled to the first SRAM cell, and the second word line is electrically coupled to the second SRAM cell; forming a bit line and a bit line bar over a back-side of the device layer, wherein the first and second SRAM cells share the bit line and the bit line bar. In some embodiments, the method further includes forming a second word lines over the front-side of the device layer and extending across the first and second SRAM cells in the first direction, wherein the second word line is electrically coupled to the second SRAM cell. In some embodiments, the bit line and the bit line bar extend along a second direction in perpendicular to the first direction. In some embodiments, from the top view, a first dimension of the first SRAM cell measured in the first direction is less than a second dimension of the first SRAM cell measured in a second direction perpendicular to the first direction. In some embodiments, the first and second SRAM cells each comprises first and second pass-gate transistors, and the method further comprises forming a first contact over the back-side of the device layer prior to the step of forming the bit line and the bit line bar, wherein the first contact extends from a first source/drain region of the first pass-gate transistor of the first SRAM cell to a second source/drain region of the first pass-gate transistor of the second SRAM cell, and the bit line is electrically coupled to the first and second SRAM cells through the first contact. In some embodiments, from the top view, the first contact has a first dimension extending in the first direction, and a second dimension extending in the first direction, and the first dimension is greater than the second dimension. In some embodiments, the method further includes forming a second contact over the back-side of the device layer prior to the step of forming the bit line and the bit line bar, wherein the second contact extends from a third source/drain region of the second pass-gate transistor of the first SRAM cell to a fourth source/drain region of the second pass-gate transistor of the second SRAM cell, and the bit line bar is electrically coupled to the first and second SRAM cells through the second contact. In some embodiments, the method further includes forming a power rail over the back-side of the device layer, wherein the first and second SRAM cells share the power rail. In some embodiments, from the top view, the power rail extends in parallel with the bit line and the bit line bar. In some embodiments, the first and second SRAM cells each comprises first and second pull-down transistors, and the method further comprises forming a contact over the back-side of the device layer prior to the step of forming the power rail, wherein the contact extends from a first source/drain region between the first and second pull-down transistors of the first SRAM cell to a second source/drain region between the first and second pull-down transistors of the second SRAM cell, and the power rail is electrically coupled to the first and second SRAM cells through the contact.

In some embodiments of the present disclosure, a method includes forming a first static random access memory (SRAM) cell and a second SRAM cell in a device layer, wherein the first and second SRAM cell each comprises a first pass-gate transistor and a second pass-gate transistor; forming a first back-side contact extending from a first source/drain region of the first pass-gate transistor of the first SRAM cell to a second source/drain region of the first pass-gate transistor of the second SRAM cell; forming a second back-side contact extending from a third source/drain region of the second pass-gate transistor of the first SRAM cell to a fourth source/drain region of the second pass-gate transistor of the second SRAM cell; forming a first back-side via over the first back-side contact; forming a second back-side via over the second back-side contact; forming a bit line over the first back-side via; forming a bit line bar over the second back-side via. In some embodiments, the method further includes forming a first word lines over a front-side of the device layer and extending across the first and second SRAM cells; forming a second word lines over the front-side of the device layer and extending across the first and second SRAM cells, wherein the first word line is electrically coupled to the first SRAM cell, and the second word line is electrically coupled to the second SRAM cell. In some embodiments, the method further includes forming a dielectric gate in the device layer, wherein the dielectric gate is in contact with and aligned with a gate structure of the first pass-gate transistor of the first SRAM cell from a top view. In some embodiments, the method further includes forming a first power rail over a front-side of the device layer and extending along a cell boundary of the first SRAM cell. In some embodiments, the first SRAM cell comprises a first pass-up transistor and a second pass-up transistor, and the first power rail is electrically couple to an sharing source/drain region between a first gate structure of the first pass-up transistor and a second gate structure of the second pass-up transistor. In some embodiments, the method further includes forming a dummy transistor in the device layer, wherein a gate structure of the dummy transistor is spaced apart from and aligned with a gate structure of the first pass-gate transistor of the first SRAM cell from a top view, wherein the first power rail is electrically couple to the gate structure of the dummy transistor. In some embodiments, the method further includes forming a second power rail over a back-side of the device layer, wherein the second power rail is electrically couple to the first power rail and overlaps with the first power rail.

In some embodiments of the present disclosure, An integrated circuit (IC) structure includes a device layer, a first word line, a second word line, a bit line, and a bit line bar. The device layer includes a first static random access memory (SRAM) cell and a second SRAM cell arranged along a first direction from a top view. The first word line is over a front-side of the device layer, wherein the first word line extends along the first direction and electrically coupled to the first SRAM cell. The second word line is over the front-side of the device layer, wherein the second word line extends along the first direction and electrically coupled to the second SRAM cell. The bit line over a back-side of the device layer, in which the bit line extends along a second direction and is electrically coupled to the first and second SRAM cells, and the second direction is different from the first direction in the top view. The bit line bar over the back-side of the device layer and at a same level height as the bit line, in which the bit line bar is electrically coupled to the first and second SRAM cells. In some embodiments, the IC structure further includes a power rail over the back-side of the device layer and at the same level height as the bit line and the bit line bar, in which the power rail is electrically coupled to the first and second SRAM cells, and from the top view, the power rail is between the bit line and the bit line bar. In some embodiments, the IC structure further includes a first power rail and a second power rail. The first power rail is over the front-side of the device layer and electrically couple to the first SRAM cell. The second power rail is over the front-side of the device layer and electrically coupled to the second SRAM cell, in which the first and second power rails extend along the second direction, and form the top view, the bit line and the bit line bar are between the first and second power rails.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a static random access memory (SRAM) array in a device layer, wherein the SRAM array comprises a first SRAM cell and a second SRAM cell adjacent to the first SRAM cell, and from a top view, the first and second SRAM cells are arranged in a first direction;
forming a first word line over a front-side of the device layer and extending across the first and second SRAM cells in the first direction, wherein the first word line is electrically coupled to the first SRAM cell; and
forming a bit line and a bit line bar over a back-side of the device layer, wherein the first and second SRAM cells share the bit line and the bit line bar.

2. The method of claim 1, further comprising:
forming a second word lines over the front-side of the device layer and extending across the first and second SRAM cells in the first direction, wherein the second word line is electrically coupled to the second SRAM cell.

3. The method of claim 1, wherein the bit line and the bit line bar extend along a second direction in perpendicular to the first direction.

4. The method of claim 1, wherein from the top view, a first dimension of the first SRAM cell measured in the first direction is less than a second dimension of the first SRAM cell measured in a second direction perpendicular to the first direction.

5. The method of claim 1, wherein the first and second SRAM cells each comprises first and second pass-gate transistors, and the method further comprises:
forming a first contact over the back-side of the device layer prior to the step of forming the bit line and the bit line bar, wherein the first contact extends from a first source/drain region of the first pass-gate transistor of the first SRAM cell to a second source/drain region of the first pass-gate transistor of the second SRAM cell, and the bit line is electrically coupled to the first and second SRAM cells through the first contact.

6. The method of claim 5, wherein from the top view, the first contact has a first dimension extending in the first direction, and a second dimension extending in the first direction, and the first dimension is greater than the second dimension.

7. The method of claim 5, further comprising:
forming a second contact over the back-side of the device layer prior to the step of forming the bit line and the bit line bar, wherein the second contact extends from a third source/drain region of the second pass-gate transistor of the first SRAM cell to a fourth source/drain region of the second pass-gate transistor of the second SRAM cell, and the bit line bar is electrically coupled to the first and second SRAM cells through the second contact.

8. The method of claim 1, further comprising:
forming a power rail over the back-side of the device layer, wherein the first and second SRAM cells share the power rail.

9. The method of claim 8, wherein from the top view, the power rail extends in parallel with the bit line and the bit line bar.

10. The method of claim 8, wherein the first and second SRAM cells each comprises first and second pull-down transistors, and the method further comprises:
forming a contact over the back-side of the device layer prior to the step of forming the power rail, wherein the contact extends from a first source/drain region between the first and second pull-down transistors of the first SRAM cell to a second source/drain region between the first and second pull-down transistors of the second SRAM cell, and the power rail is electrically coupled to the first and second SRAM cells through the contact.

11. A method, comprising:
forming a first static random access memory (SRAM) cell and a second SRAM cell in a device layer, wherein the first and second SRAM cell each comprises a first pass-gate transistor and a second pass-gate transistor;
forming a first back-side contact extending from a first source/drain region of the first pass-gate transistor of the first SRAM cell to a second source/drain region of the first pass-gate transistor of the second SRAM cell;
forming a second back-side contact extending from a third source/drain region of the second pass-gate transistor of the first SRAM cell to a fourth source/drain region of the second pass-gate transistor of the second SRAM cell;
forming a first back-side via over the first back-side contact;
forming a second back-side via over the second back-side contact;
forming a bit line over the first back-side via; and
forming a bit line bar over the second back-side via.

12. The method of claim 11, further comprising:
forming a first word lines over a front-side of the device layer and extending across the first and second SRAM cells; and
forming a second word lines over the front-side of the device layer and extending across the first and second SRAM cells, wherein the first word line is electrically coupled to the first SRAM cell, and the second word line is electrically coupled to the second SRAM cell.

13. The method of claim 11, further comprising:
forming a dielectric gate in the device layer, wherein the dielectric gate is in contact with and aligned with a gate structure of the first pass-gate transistor of the first SRAM cell from a top view.

14. The method of claim 11, further comprising:
forming a first power rail over a front-side of the device layer and extending along a cell boundary of the first SRAM cell.

15. The method of claim 14, wherein the first SRAM cell comprises a first pass-up transistor and a second pass-up transistor, and the first power rail is electrically couple to an sharing source/drain region between a first gate structure of the first pass-up transistor and a second gate structure of the second pass-up transistor.

16. The method of claim 14, further comprising:
forming a dummy transistor in the device layer, wherein a gate structure of the dummy transistor is spaced apart from and aligned with a gate structure of the first pass-gate transistor of the first SRAM cell from a top view, wherein the first power rail is electrically couple to the gate structure of the dummy transistor.

17. The method of claim 14, further comprising:
forming a second power rail over a back-side of the device layer, wherein the second power rail is electrically couple to the first power rail and overlaps with the first power rail.

18. An integrated circuit (IC) structure, comprising
a device layer comprising a first static random access memory (SRAM) cell and a second SRAM cell arranged along a first direction from a top view;
a first word line over a front-side of the device layer, wherein the first word line extends along the first direction and electrically coupled to the first SRAM cell;
a second word line over the front-side of the device layer, wherein the second word line extends along the first direction and electrically coupled to the second SRAM cell;
a bit line over a back-side of the device layer, wherein the bit line extends along a second direction and is electrically coupled to the first and second SRAM cells, and the second direction is different from the first direction in the top view; and
a bit line bar over the back-side of the device layer and at a same level height as the bit line, wherein the bit line bar is electrically coupled to the first and second SRAM cells.

19. The IC structure of claim 18, further comprising:
a power rail over the back-side of the device layer and at the same level height as the bit line and the bit line bar, wherein the power rail is electrically coupled to the first and second SRAM cells, and from the top view, the power rail is between the bit line and the bit line bar.

20. The IC structure of claim 18, further comprising:
a first power rail over the front-side of the device layer and electrically couple to the first SRAM cell; and
a second power rail over the front-side of the device layer and electrically coupled to the second SRAM cell, wherein the first and second power rails extend along the second direction, and form the top view, the bit line and the bit line bar are between the first and second power rails.
